(19) United States
(12) Patent Application Publication
(10) Pub. No.: US 2025/0151328 A1
(43) Pub. Date: May 8, 2025

(54) MICROELECTRONIC DEVICE COMPRISING A WRAPPING GRID AND METHOD FOR PRODUCING SUCH A DEVICE

(71) Applicant: COMMISSARIAT A L'ENERGIE ATOMIQUE ET AUX ENERGIES ALTERNATIVES, Paris (FR)

(72) Inventor: Sylvain BARRAUD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/799,638

(22) Filed: Aug. 9, 2024

(30) Foreign Application Priority Data
Aug. 11, 2023 (FR) 2308691

(51) Int. Cl. H10D 30/67; H10D 30/01; H10D 62/80; H10D 64/01

(52) U.S. Cl. CPC H10D 30/6735; H10D 30/0312; H10D 30/6757; H10D 62/883; H10D 64/017

(57) ABSTRACT

The invention relates to a microelectronic device comprising a transistor (T1, T2) comprising

at least two channels (41a, 41b, 41c) stacked along a main direction (z),. a first gate (G1) partially surrounding one of the channels (41a, 41b, 41c),

a second gate (G2) partially surrounding said channel (41),

a source (42) and a drain (43) either side of the channels (41a, 41b, 41c), and source and drain contacts (60S, 60, 60D) connected respectively to the source (42) and to the drain (43),

a gate dielectric layer (70, 71, 72) separating each channel (41) of the gates-all-around (G1, G2).

The first and second gates (G1, G2) are isolated from one another, such that they can be independently biased.

The invention also relates to a method for producing such a device.

### TECHNICAL FIELD

The invention relates to the field of microelectronic technologies. It has a particularly advantageous application in manufacturing advanced gate-all-around and semiconductive material-based channel FET (Field-Effect Transistor)-type devices, in particular two-dimensional (2D) material-or semiconductive oxide-based.

### PRIOR ART

The constant increase of performance of transistors has first been made possible by reducing transistor dimensions, for a conventional silicon-based MOSFET (Metal-Oxide-Semiconductor Field-Effect Transistor) architecture.

This conventional architecture has then given way to other types of architectures, better adapted to performances specified in technology nodes less than 12 nm. The so-called “finFET” architecture makes it possible, for example, to respond to the performances set by 7 nm and 5 nm technology nodes. Such an architecture makes it possible, in particular, to easily adjust the threshold voltage of transistors to favour high performance or low energy consumption, according to the targeted applications.

For the next technology nodes, in particular, from 3 nm and beyond, other architectures offering a better electrostatic control are necessary. An architecture considered to respond to the problems of these next technology nodes comprises so-called GAA (Gate-All-Around) transistors. These GAA transistors typically comprise very thin channels, in the form of nanowires or nanosheets, stacked on one another. This type of architecture is however less versatile than “finFET” architecture. The threshold voltage cannot be easily adjusted.

The document, “Multiple-Vt Solutions in Nanosheet Technology for High Performance and Low Power Applications, R. Bao et al., 2019 IEEE International Electron Devices Meeting (IEDM)” discloses a solution making it possible to integrate nanosheet GAA transistors having a multitude of threshold voltages. The device and the method disclosed by this document are based on the introduction of variable nanosheet dimensions within one same stack, with a good gate dimensional control. The different gate-all-around portions thus have different metal thicknesses. This makes it possible to obtain different threshold voltages for one same stack. Four different threshold voltages are thus accessible via this architecture. To increase the number of accessible threshold voltages, different zones, made with different technological parameters, remain necessary.

A major challenge for the development of these GAA transistor architectures is the option to finely adjust their threshold voltage.

A first aim of the invention is to propose a GAA transistor architecture enabling an extended control of the threshold voltage. A second aim of the invention is to propose a method for producing such a GAA transistor architecture. Another aim of the invention is to overcome at least some of the disadvantages of known devices and methods.

### SUMMARY

To achieve these aims, according to an embodiment, a microelectronic device is provided, comprising at least one transistor comprising:
at least two channels stacked along a main direction z, each channel being with the basis of a semiconductive material,
a gate surrounding at least one of the channels,
a source and a drain either side of each channel, and source and drain contacts connected respectively to the source and to the drain,
a gate dielectric layer separating each channel and the gate-all-around.

The gate corresponds to a first gate partially surrounding at least one of the channels.

Advantageously, the at least one transistor comprises a second gate partially surrounding the same channel as that surrounded by the first gate, the first and second gates being electrically isolated from one another, such that they can be biased independently from one another.

Thus, the device comprises two gates surrounding the transistor channels, which can be biased independently. This makes it possible to adjust the threshold voltage of the device continuously, contrary to known solutions which make it possible to only access a few threshold voltages fixed beforehand by the design of the architecture. The device according to the invention advantageously has an extended range of threshold voltages for a GAA architecture. It can be qualified as a dual gate device. The gate dielectric layer can have ferroelectric properties, for example, to produce feFET (ferroelectric field-effect transistor)-type memory transistors.

Another aspect of the invention relates to a method for manufacturing this microelectronic device. The method comprises the following steps:
Providing, on a substrate, a stack along the main direction z comprising a plurality of first layers made of a first material alternated with a plurality of second layers made of a second material alternated with a plurality of third layers made of a third material, the first, second and third materials being different,
Forming a first etching mask on this stack,
Forming, in this stack, first openings defining first patterns in vertical alignment with the first etching mask,
Forming a sacrificial gate either side of the first patterns, in the first openings,
Forming a second etching mask on the first etching mask and on the sacrificial gate, the second etching mask being transverse to the first etching mask,
Forming, in the first patterns, second openings defining second patterns in vertical alignment with the second etching mask,
Partially removing, from the second openings, the third material of the third layers selectively at the first and second materials of the first and second layers, so as to form third spaces in the third layers,
Filling the third spaces with a third dielectric material to form third internal spacers,
Partially removing, from the second openings, the first material of the first layers selectively at the second material of the second layers and at the third internal spacers, so as to form first spaces in the first layers, preferably in vertical alignment with the third internal spacers,
Filling the first spaces with a first dielectric material to form first internal spacers,
Partially removing the sacrificial gate, so as to form third openings opening onto the remaining parts of the third layers,
Totally removing, from the third openings, the third material of the remaining parts of the third layers, so as to form third cavities,
Forming a first dielectric layer in the third cavities,
Filling the third cavities with a first metal material, so as to form the first gate partially surrounding the second layers,
Totally removing a remaining part of the sacrificial gate, so as to form fourth openings opening onto the remaining parts of the first layers,
Totally removing, from the fourth openings, the first material of the remaining parts of the first layers, so as to form first cavities,
Forming a second dielectric layer in the first cavities,
Filling the first cavities with a second metal material, so as to form the second gate partially surrounding the second layers,
Filling the second openings with an electrically conductive material, so as to form source and drain contacts in contact with the second layers.

A principle of the method according to the invention consists of selectively replacing certain layers of the initial stack, in this case, the first and third layers, to form two typically interdigitated gate parts, surrounding the layers with the basis of a semiconductive material forming the transistor channels, in this case, the second layers. The advantages mentioned above for the device apply mutatis mutandis to the method according to the invention.

According to an option, the second layers are subsequently replaced with a semiconductive material, in order to form the transistor channels. In this case, the initial stack does not comprise the semiconductive material forming the transistor channels. The subsequent deposition of the semiconductive material aims to better preserve the semiconductive material. According to a preferred option, the semiconductive material is a two-dimensional (2D) material chosen from among MX2 transition metal dichalcogenides, with M taken from among molybdenum (Mo) or tungsten (W), and X taken from among sulphur(S) or selenium (Se). The method makes it possible, in particular, to introduce 2D material layers at the end of the method, after structuration of the stack, and in particular, after the formation of the internal spacers. This advantageously makes it possible to limit the risk of degradation of the 2D material during the method. The 2D material is not exposed to all the steps of the manufacturing method. The 2D material is thus preserved.

Such a late introduction of the 2D material during the manufacturing method, further makes it possible to use standard microelectronic technologies for the formation and the structuration of the stack. It is not necessary to modify or adapt the standard structuration technological steps to the use constraints of the 2D material. The costs of the method are thus advantageously limited. The method can further be more easily implemented in current production lines.

Other aims, features and advantages of the present invention will appear upon examining the description below and the accompanying drawings. It is understood that other advantages can be incorporated.

### BRIEF DESCRIPTION OF THE FIGURES

FIGS. 1A, 2A, 3A, 4A, 5A, 6A, 7A, 8A, 9A, 10A, 11A, 12A, 13A, 14A, 15A, 16A, 17A, 18A, 19A, 20A, 21A, and 22A schematically illustrate, along transverse cross-sections xz of the steps of manufacturing a superposed channel device, according to a first embodiment of the present invention.

FIGS. 1B, 2B, 3B, 4B, 5B, 6B, 7B, 8B, 9B, 10B, 11B, 12B, 13B, 14B, 15B, 16B, 17B, 18B, 19B, 20B, 21B, and 22B schematically illustrate, along transverse cross-sections yz indicated in corresponding figures, the same steps of manufacturing the device, according to a first embodiment of the present invention.

FIGS. 23A, 24A, 25A, 26A, 27A, 28A, 29A, 30A, 31A, 32A, 33A, and 34A schematically illustrate, along transverse cross-sections xz of the steps of manufacturing a superposed channel device, according to a second embodiment of the present invention.

FIGS. 23B, 24B, 25B, 26B, 27B, 28B, 29B, 30B, 31B, 32B, 33B, and 34B schematically illustrate, along transverse cross-sections yz indicated in corresponding figures, the same steps of manufacturing the device, according to a second embodiment of the present invention.

FIGS. 35A and 36A schematically illustrate, along transverse cross-sections xz of the variants of a superposed channel device, according to another embodiment of the present invention.

FIGS. 35B and 36B schematically illustrate, along transverse cross-sections yz indicated in corresponding figures, the same variants of the device, according to another embodiment of the present invention.

In the figures in transverse cross-sections, cutting planes are indicated (A-A′, B-B′, . . . , P-P′ . . . , Z-Z′, α-α′, . . . , ε-ε′, . . . , λ-λ′) with references crossed with the cutting planes of the corresponding figures. The drawings are given as examples and are not limiting of the invention. They constitute principle schematic representations intended to facilitate the understanding of the invention and are not necessarily to the scale of practical applications. In particular, in the principle diagrams, the thicknesses and/or the dimensions of the different layers, patterns and raised elements are not representative of reality. For reasons 15 of clarity, all of the alphanumerical references are not systematically repeated from one figure to another. It is understood that the elements already described and referenced, when they are reproduced in another figure, typically have the same alphanumerical references, even if these are not explicitly mentioned. A person skilled in the art will identify, without difficulties, one same element reproduced in different figures.

### DETAILED DESCRIPTION

Before starting a detailed review of embodiments of the invention, optional features are stated below which can optionally be used in association or alternatively:

According to an example, each channel is partially surrounded by the first gate and is partially surrounded by the second gate.

According to an example, the first gate and the second gate are interdigitated.

According to an example, each channel is inserted between a finger of the first gate and a finger of the second gate.

According to an example, the first gate covers two adjacent sides of one of the channels, and the second gate covers two other adjacent sides of this channel.

According to an example, the first and second gates have complementary shapes completely surrounding at least one of the channels, in particular surrounding all the sides of this channel.

According to an example, the semiconductive material is an MX2 transition metal dichalcogenide, with M taken from among molybdenum (Mo) or tungsten (W), and X taken from among sulphur(S), selenium (Se) or tellurium (Te).

According to another example, the semiconductive material is with the basis of a semiconductive oxide, for example, IGZO (indium gallium zinc oxide)-, In2O3-, IWO (tungsten-doped indium oxide)-, ITO (indium tin oxide)-, IAZO (indium aluminium zinc oxide)-, InGaZnO-, InGaO-, InZnO-based or an amorphous semiconductive oxide.

According to another example, the semiconductive material is graphene-, hexagonal boron nitride “h-BN”-, phosphorene-based.

According to an example, the stack comprises an alternance of a first layer with a second layer with a third layer. Preferably, the initial stack does not comprise neither the semiconductive material of the transistor channels, nor the materials of the different gates or gate-all-around parts. According to an example, the first layers of the stack provided are only in contact with the second layers and the third layers of the stack provided are only in contact with the second layers.

According to an example, the first and third internal spacers are silicon nitride-based. The first internal spacers are preferably in contact with the remaining parts of the first layers.

The third internal spacers are preferably in contact with the remaining parts of the third layers. Before formation of the first internal spacers, the partial removal of the first material from the first layers is configured to preserve parts of the first layers between the first spaces. These parts are called remaining parts. The remaining parts of the first layers are thus located between the first spaces, along a direction of the plane xy. Before formation of the third internal spacers, the partial removal of the third material from the third layers is configured to preserve parts of the third layers between the third spaces. These parts are called remaining parts. The remaining parts of the third layers are thus located between the third spaces, along a direction of the plane xy.

According to an example, the method further comprises a sequence of steps configured to replace the second layers, said sequence comprising the following steps:
Totally removing, from the second openings, the second material of the second layers, for example, selectively at the first material of the first layers, so as to form second spaces,
Preferably forming a dielectric layer in the second spaces,
Depositing a layer with the basis of a semiconductive material in the second spaces, so as to form:
   channels with the basis of the semiconductive material in vertical alignment with the first and second gates, under the first and second etching masks, and
   sources and drains with the basis of the semiconductive material in vertical alignment with the first and third internal spacers.

Typically, for CMOS applications (MOSFET transistors), the dielectric layer does not have ferroelectric properties. For memory applications (FeFET transistors), this dielectric layer has ferroelectric properties.

According to an example, the sequence of steps configured to replace the second layers is carried out after formation of the first and third internal spacers and the formation of the source and drain contacts is done after said sequence of steps and before the partial removal of the sacrificial gate. This type of method, typically called “gate last”, or in this case, “dual gate last”, provides the formation of the functional gate at the end of the method, in replacement of the sacrificial gate. This makes it possible to preserve the dimensional features of the first and second gates. This makes it possible to obtain a better control of the threshold voltage of MOSFET transistors. The thermal budget linked to the deposition of the layer with the basis of semiconductive material does not impact the equivalent gate oxide thickness at the interface with the first and second gates. The structural and electrical features of the two functional gates are better controlled.

According to an example, the sequence of steps configured to replace the second layers is carried out after formation of the first and second gates and before formation of the source and drain contacts. This type of method, typically called “gate first”, or in this case, “dual gate first”, or also “channel last”, provides the formation of the functional gate in replacement of the sacrificial gate at the start of the method. The channels are formed at the end of the method. This makes it possible to preserve the properties of the channels, in particular when the transistor channels are with the basis of a material which is sensitive to temperature.

According to an example, the method further comprises a formation of spacers on the flanks of the first and second etching masks, said spacers bearing on an upper face of the first patterns.

According to an example, the deposition of the layer with the basis of the semiconductive material is also done on the flanks of the second pattern, substantially parallel to the main direction z, in particular on the flanks of the first internal spacers and on the flanks of the third internal spacers. This makes it possible to facilitate the return of the source and drain contacts in the device.

According to an example, the deposition of the layer with the basis of the semiconductive material is configured to form layer side portions with the basis of the semiconductive material on the flanks of the second pattern, substantially parallel to the main direction z, and layer horizontal portions with the basis of the semiconductive material in the second spaces, such that the side portions are thicker than the horizontal portions. Thicker side portions make it possible to decrease the contact resistance of the source and drain contacts. The transistor channels are formed in the horizontal portions.

According to an example, the deposition of the layer with the basis of the semiconductive material is configured to form side layer portions with the basis of the semiconductive material on the spacers, on the first internal spacers and on the third internal spacers.

According to an example, the method comprises a formation of source and drain contacts in the second openings.

According to an example, the deposition of the layer with the basis of the semiconductive material is done by chemical vapour deposition or by atomic layer deposition. Chemical vapour depositions are easy to implement. Atomic layer depositions make it possible to precisely control the thickness of the layer with the basis of the semiconductive material. These depositions make it possible to obtain a very good conformity for the layer with the basis of the semiconductive material.

According to an example, the semiconductive material is chosen from among MX2 transition metal dichalcogenides, with M taken from among molybdenum (Mo) or tungsten (W), and X taken from among sulphur(S), selenium (Se) or tellurium (Te).

According to another example, the semiconductive material is chosen with the basis of a semiconductive oxide, for example, IGZO (indium gallium zinc oxide)-, In2O3-, IWO (tungsten-doped indium oxide)-, ITO (indium tin oxide)-, IAZO (indium aluminium zinc oxide)-, InGaZnO-, InGaO-, InZnO-based or an amorphous semiconductive oxide.

According to an example, the first material is chosen as SiGe with a concentration of germanium of between 20 at. % and 25 at. %, the second material is chosen as Si, and the third material is chosen as SiGe with a concentration of germanium of around 50 at. %. These materials can be easily epitaxially grown by conventional microelectronic technological methods. This makes it possible to benefit from current technological methods. The cost of the method is reduced. The assignment of the different materials to the different layers can be permuted.

According to an example, the formation of the sacrificial gate is done, such that the sacrificial gate extends over the entire height of the first openings. According to an example, the first openings extend along the entire height of the stack of the first, second and third layers. The sacrificial gate extends over the entire height of the stack. The sacrificial gate typically bears on the substrate. This makes it possible to give an access to all the layers of the stack via the third and fourth openings.

According to an example, the deposition of the layer with the basis of the semiconductive material is configured, such that the layer with the basis of the semiconductive material totally fills the second spaces.

According to another example, the deposition of the layer with the basis of the semiconductive material is configured, such that the layer with the basis of the semiconductive material partially fills the second spaces. According to an example, the method further comprises, after deposition of the layer with the basis of the semiconductive material, a deposition of an additional dielectric layer configured to fill the second spaces. This makes it possible to form a layer with the basis of the thin semiconductive layer, without constraint on the thickness of the second layers of the stack. The layer with the basis of the semiconductive material can have a thickness less than that of the second layers of the initial stack.

According to an example, the substrate is a silicon-based bulk substrate.

According to an example, the first openings are formed along a longitudinal direction x and the second openings are formed along a transverse direction y perpendicular to the longitudinal direction x, said first and second openings extending to the substrate.

According to an example, the removal of the first material from the first layers is done selectively at the second material of the second layers with a selectivity S_{10:20} of at least 5:1, preferably at least 10:1. According to an example, the removal of the third material from the third layers is done selectively at the second material of the second layers with a selectivity S_{30:20} of at least 5:1, preferably at least 10:1.

According to an example, the removal of the second material from the second layers is done selectively at the first material of the first layers with a selectivity S_{20:10} of at least 5:1, preferably at least 10:1. According to an example, the removal of the second material from the second layers is done selectively at the third material of the third layers with a selectivity S_{20:30} of at least 5:1, preferably at least 10:1.

According to an example, the deposition of the layer with the basis of the semiconductive material is configured to form layer side portions with the basis of the semiconductive material on the flanks of the second pattern in the second openings. According to an example, the method further comprises a formation of source and drain contacts in said second openings and on the layer side portions with the basis of the semiconductive material, before the start of the removal of the sacrificial gate, or after formation of the first and second gates.

Unless incompatible, it is understood that all of the optional features above can be combined, so as to form an embodiment which is not necessarily illustrated or described.

Such an embodiment is clearly not excluded from the invention. The features and the advantages of an aspect of the invention, for example, the device or the method, can be adapted mutatis mutandis to the other aspect of the invention.

The invention generally relates to a GAA transistor microelectronic device and a manufacturing method. Such a microelectronic device can have a “GAA stacked nanosheet”-type architecture, i.e. with stacked nanosheets and partially or totally gate-all-around. A stacked nanowire and partially or totally gate-all-around architecture is also possible.

The nanowires or nanosheets typically each comprise a conduction channel of a transistor. These channels are stacked along a direction z. This means that they each occupy a given altitude level along the direction z. A level can be defined between two planes perpendicular to the direction z.

In the present invention, each transistor comprises two gates. These two gates each comprise portions surrounding the transistor channels. These portions can typically be complementary, so as to totally or almost totally surround at least one of the transistor channels. These two gates can be called “all-around”, even if each gate does not totally coat the transistor channel(s). The combination of the two gates can be similar to a gate totally surrounding the transistor channel(s). This architecture therefore falls under both “Gate-All-Around” and “Dual Gate” nomenclatures.

Advantageously, the method according to the invention can be implemented to produce MOS GAA transistors for 5 nm and sub-5 nm technology nodes.

A microelectronic device comprising superposed channel GAA transistors can be advantageously integrated in logic systems having 3D architectures. These transistors can, in particular, be associated with other structural or functional elements, so as to design complex systems.

A particular aspect of the invention relates to the implementation of 2D materials to produce nanowires or nanosheets of the device. These 2D materials have semiconductive properties, in particular by the presence of an electronic gap.

The 2D materials typically correspond to compounds having a lamellar structure constituted of two-dimensional sheets, stacked along the crystallographic axis c. The atomic bonds within each sheet are strong, of covalent nature. The bonds between sheets are a lot weaker, of the Van der Waals type. These two-dimensional sheets are also called monolayers.

In the scope of the present invention, the monolayers are preferably semiconductive monolayers of the MX2 type, where M is molybdenum (Mo) or tungsten (W) and X, sulphur (S) or selenium (Se). Each “monolayer” is, in this case, composed of a metal cation plane M inserted between two anion planes X. A monolayer therefore comprises, in this case, typically three atomic planes: the atoms of the transition metal (Mo or W) form a plane sandwiched between two chalcogen planes (S, Se or Te, for example). Each transition metal atom is connected to six chalcogen atoms. These anions are in prismatic trigonal coordination with respect to the metal atoms. The MX2 transition metal dichalcogenide monolayers have a hexagonal atomic array.

The MX2 transition metal dichalcogenide monolayers are preferably with the basis of MoS2, MoSe2, MoTe2, WS2, WSe2 molybdenum disulphide.

An alternative option relates to the implementation of semiconductive oxides to produce the nanowires or nanosheets of the device, for example, IWO, IGZO, ITO, InGaZnO, InGaO, InZnO, In2O3, IAZO. Another option relates to the implementation of graphene, hexagonal boron nitride “h-BN”, phosphorene (also called “Black Phosphorous” BP), in particular, in the form of a monolayer.

It is specified that, in the scope of the present invention, the terms “on”, “surmounts”, “covers”, “underlying”, “opposite” and their equivalents do not necessarily mean “in contact with”. Thus, for example, the deposition or the application of a first layer on a second layer, does not compulsorily mean that the two layers are directly in contact with one another, but means that the first layer covers at least partially the second layer by being either directly in contact with it, or by being separated from it by at least one other layer or at least one other element.

By a substrate, a film, a layer “with the basis” of a material A, this means a substrate, a film, a layer comprising this material A only or this material A and optionally other materials, for example, doping elements or alloy elements. Thus, a silicon nitride SiN-based spacer can, for example, comprise non-stoichiometric silicon nitride (SiN), or stoichiometric silicon nitride (Si3N4), or also a silicon oxy-nitride (SiON).

The word “dielectric” qualifies a material, the electrical conductivity of which is sufficiently low in the given application to serve as an isolator. In the present invention, a dielectric material preferably has a dielectric constant less than 20. In the present invention, the dielectric layer can have ferroelectric properties.

Several embodiments of the invention implementing successive steps of the manufacturing method are described below. Unless explicitly mentioned, the adjective “successive” does not necessarily imply, even if this is generally preferred, that the steps follow one another immediately, intermediate steps being able to separate them.

Moreover, the term “step” means the carrying out of some of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

The different patterns formed during the manufacturing steps typically have a structure intended to evolve during the steps of the method. Thus, the patterns can comprise the sacrificial layers of the initial stack, the 2D material- or semiconductive oxide-based layers, the dielectric layers, continuous or discontinuous. The different patterns aim to form, at the end of the method, “transistor patterns”, each comprising at least one conduction channel and one gate surrounding said channel, one dielectric barrier separating the gate and the channel, one source and one drain either side of the channel. The assignment of the first and second layers in the initial stack can be inverted.

A preferably orthonormal system, comprising the axes x, y, z is represented in the accompanying figures.

In the present patent application, thickness will preferably be referred for a layer or a film, and height will preferably be referred to for a device or a structure. The thickness is taken along a direction normal to the main extension plane of the layer or of the film. Thus, a superficial silicon (topSi) layer typically has a thickness along z. A gate pattern formed on such a superficial layer has a height along z. The relative terms “on”, “surmounts”, “under”, “underlying” refer to positions taken along the direction z. The terms “vertical”, “vertically” refer to orientations along the direction z. A “lateral” dimension corresponds to a dimension along a direction of the plane xy. By a “lateral” extension, this means an extension along one or more directions of the plane xy.

An element located “in vertical alignment with” or “to the right of” another element means that these two elements are both located on one same line perpendicular to a plane into which a lower or upper face of a substrate mainly extends, i.e. on one same line oriented vertically in the figures in transverse cross-section.

The terms “substantially”, “about”, “around” mean plus or minus 10%, and preferably plus or minus 5%. Moreover, the terms “between . . . and . . . ” and equivalents mean that the limits are included, unless mentioned otherwise.

The description below has examples of implementation of the method according to the invention in a context of developing a complex 3D device. The scope of this description is clearly not limiting of the invention.

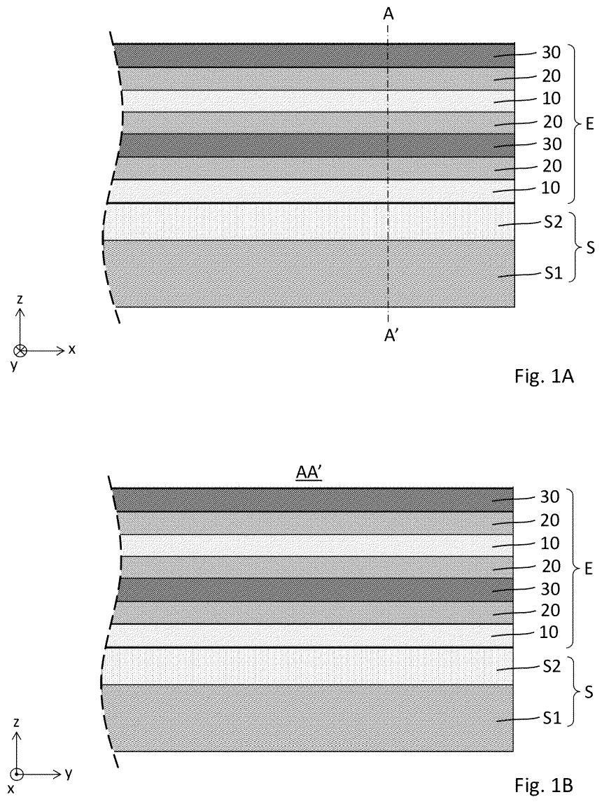

FIGS. 1A, 1B à 22A, 22B schematically illustrate steps of manufacturing a device comprising GAA transistors according to a first embodiment. Figures nA (n=1 . . . 22) correspond to first transverse cross-sections, each illustrating a different step of the manufacturing method. Figures nB (n=1 . . . 22) correspond to second transverse cross-sections, each illustrating the same step as corresponding figure nA. This first embodiment can, in particular, be qualified as “gate last” or “dual gate last”. The first and second gates are, in this case, formed at the end of the method, after formation of the transistor channels.

As illustrated in FIGS. 1A, 1B, a first step consists of producing a stack E of semiconductive layers 10, 20, 30 on a substrate S. The substrate S can be an SOI (silicon on insulator)-, GeOI (germanium on insulator)-, or SGOI (silicon-germanium on insulator)-type substrate. These known substrates comprise, according to common terminology for a person skilled in the art, a thick silicon layer S1 called “Si bulk”, a silicon oxide layer S2 called “BOX” (buried oxide) and a superficial thin layer, respectively silicon-, germanium- or silicon-germanium-based. This superficial thin layer can advantageously correspond to the first layer 10 of the stack E.

Alternatively, the substrate S can be an “Si bulk” bulk substrate.

The stack E comprises, according to an example, an alternance of silicon-germanium (SiGe) first layers 10 having a first Ge composition, of silicon (Si) second layers 20, and of SiGe third layers 30 having a second Ge composition.

The concentrations of Ge in the SiGe alloy of the first and third layers 10, 30 are chosen so as to enable a good etching selectivity during the selective etching steps between the different layers. According to an example, the first layers 10 have a first Ge composition of between 20 at. % and 25 at. %. According to an example, the third layers 30 have a second Ge composition of around 50 at. %. This stack E is advantageously formed by epitaxy of the SiGe 10, 30 and Si 20 layers. This step of forming the stack E is inexpensive and well-known to a person skilled in the art. The thicknesses of the Si and SiGe layers can by typically around 10 nm, and more generally, between 5 nm and 20 nm, for example. In a known manner, in order to avoid the formation of structural defects, the maximum thicknesses permitted for the SiGe layers 10, 30 depend, in particular, on the concentration of Ge chosen.

In the example illustrated in FIGS. 1A, 1B, two SiGe layers 10 are alternated with three epitaxially grown Si layers 20 and two SiGe layers 30. An Si/SiGe super array is thus obtained. The number of Si and SiGe layers can naturally be increased. This ultimately makes it possible to increase the number of channels stacked in the final device. The sequence of the first, second and third layers 30 is preferably chosen, such that each second layer 20 is inserted between a first layer 10 and a third layer 30. In the final device, the first layers are intended to be replaced with fingers of a first gate and the third layers are intended to be replaced with fingers of a second gate, the first and second gates being interdigitated. The second layers are intended to form transistor channels, partially surrounded by the first gate and partially surrounded by the second gate. The sequence of different layers 10, 20, 30 is therefore chosen according to the design sought for the final device. According to an example, the first layers 10 are only in contact with the second layers 20 and the third layers 30 are also only in contact with the second layers 20.

Generally, the first material of the first layers 10, the second material of the second layers 20 and the third material of the third layers 30 are chosen, such that each can be etched selectively with respect to the others. Thus, other pairs of first, second and third materials are possible. By respecting this etching selectivity condition, the first, second and third materials can be chosen from among dielectric materials (oxides and nitrides, for example), semiconductive materials, metal materials. It will be ensured, in particular, that the third material can be etched selectively with respect to the first and second materials, and that the first material can be etched selectively with respect to the second material.

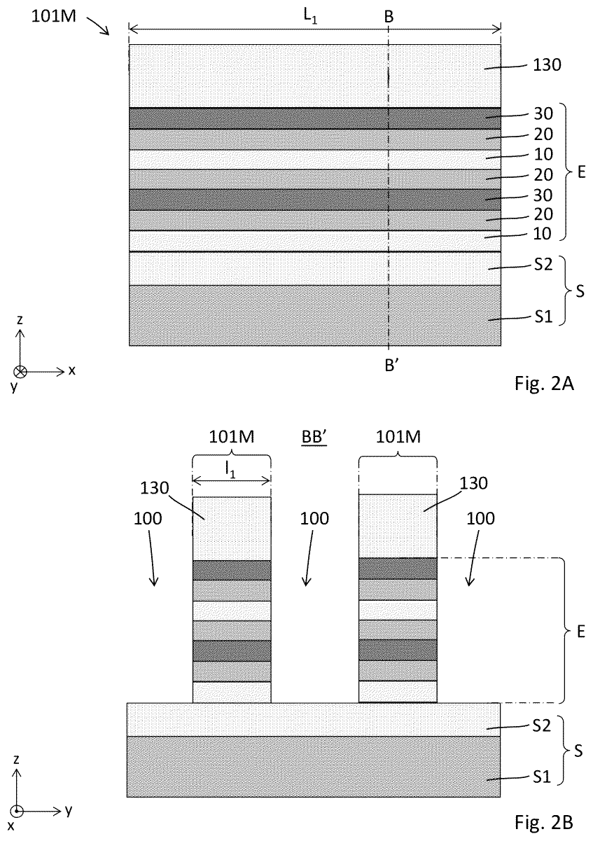

As illustrated in FIGS. 2A, 2B, a conventional lithography/etching step is carried out, in order to define first patterns 101M, and first openings 100. The etching is anisotropic and directed along z. It is configured to etch the stack E, in this case, the Si/SiGe super array, over its entire height, by stopping on the substrate S, in this case, the BOX S2. It can be done by plasma by using an HBr/O2 etching chemistry. The first patterns 101M can have a length L₁ along x of between 10 nm and 500 nm. They preferably have a width I₁ along y of between 10 nm and 120 nm, for example, of around 40 nm. This first structuration of the stack E in the form of fins, makes it possible to define a plurality of superposed nanowires or nanosheets. The “fin” patterns 101M are typically surmounted by an etching mask or hard mask 130 implemented during this first structuration of the stack E.

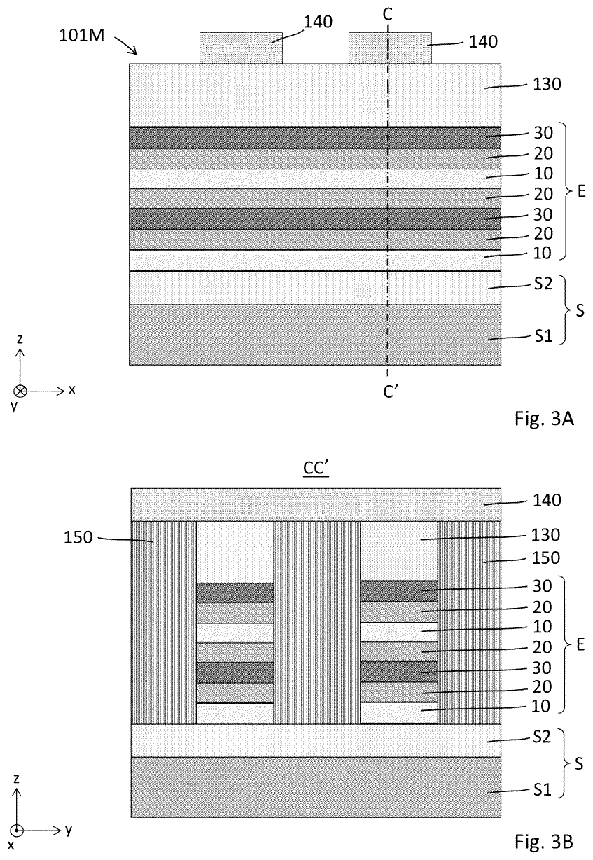

As illustrated in FIGS. 3A, 3B, sacrificial gates 150 are then formed on the “fin” patterns 101M. The formation of these sacrificial gates 150 is done typically by deposition then chemical-mechanical polishing CMP, stopping on the hard mask 130. The sacrificial gates 150 typically comprise several independent portions located between the “fin” patterns 101M. This subsequently facilitates a localised opening of the different portions of the sacrificial gates. The sacrificial gates 150 typically bear on the substrate S. An etching mask or hard mask 140 is formed transversally to the “fin” patterns 101M. This hard mask 140 then contributes to a second structuration of the stack E, as well as to a structuration of the sacrificial gates 150, as illustrated in the following figures. The sacrificial gates 150 are, for example, polycrystalline silicon-based. A thin SiO₂ oxide layer, of thickness 7 nm, for example, is preferably deposited prior to the formation of the sacrificial gates 150. This thin SiO₂ oxide layer (not illustrated in the figures) is thus inserted between the sacrificial gates 150 and the “fin” patterns 101M. This thin SiO₂ oxide layer can form a stop layer for the subsequent etching of the sacrificial gates 150.

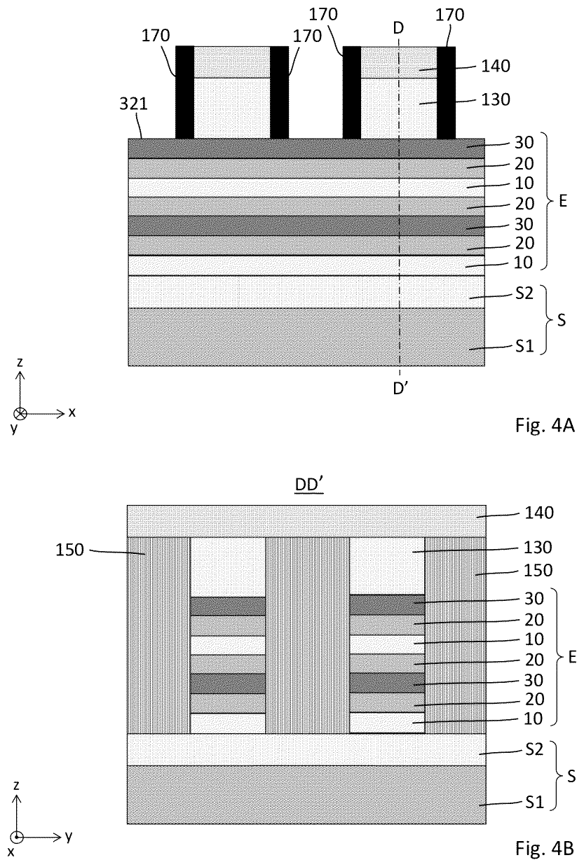

As illustrated in FIGS. 4A, 4B, the hard mask 130 is first etched, so as to expose the upper face 321 of the stack E. The hard mask portions 130 located under the hard mask 140 are preserved, as well as the hard mask 140. Spacers 170 are then formed on the flanks oriented along yz of the hard masks 130, 140. Generally, projecting along z, these spacers form a continuous ring around the hard masks 130, 140, with a closed contour. In transverse cross-section, however, along the plane xz illustrated in FIG. 4A, the spacer 170 has two parts opposite one another on each of the flanks of the hard masks 130, 140. These two parts are generally called the spacers 170, even if these can be considered as belonging to one single and same spacer. The spacers 170 extend typically to the upper face 321 of the stack E. The spacers 170 are typically silicon nitride SiN-based or with the basis of a dielectric material with low dielectric constant, for example, SiCO-based.

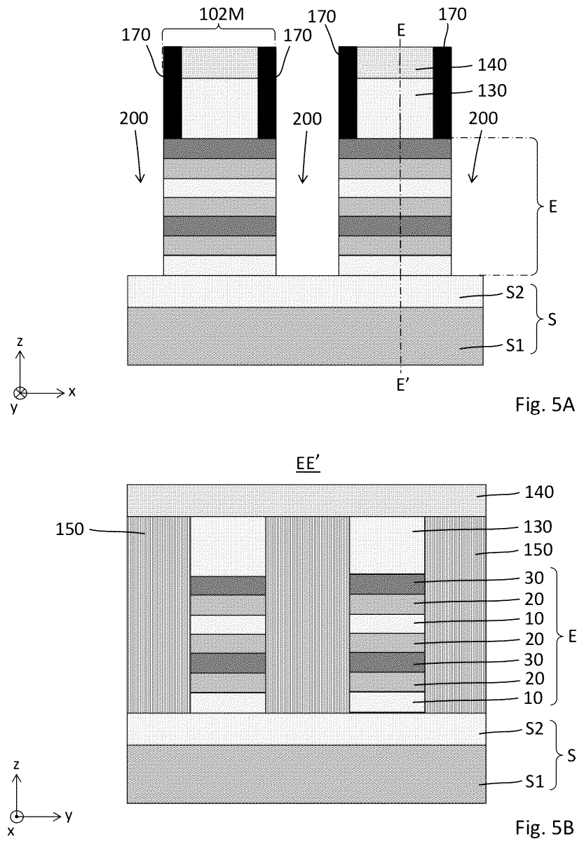

As illustrated in FIGS. 5A, 5B, after formation of the spacers 170 by deposition/etching, the anisotropic etching along z is extended, in order to define second patterns 102M, and second openings 200. The etching is configured to etch the stack E over its entire height, by stopping on the substrate S. It can be done by plasma, by using an HBr/O2 etching chemistry. A second structuration of the stack E is thus done.

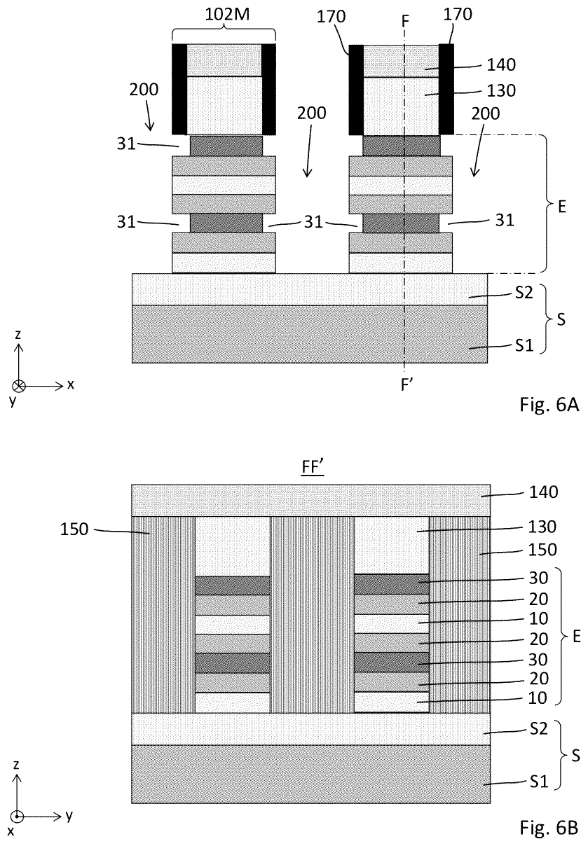

As illustrated in FIGS. 6A, 6B, after formation of the second openings 200, the third openings 30 are partially etched selectively at the second layers 20, at the first layers 10, at the substrate S and at the spacers 170. The etching of the third material of the third layers 30 typically has a selectivity S_{30:20} with respect to the second material of the second layers 20, of at least 5:1, preferably at least 10:1. The etching of the third material of the third layers 30 typically has a selectivity S_{30:10} with respect to the first material of the first layers 10, of at least 5:1, preferably at least 10:1. This partial etching aims to form third spaces 31 in vertical alignment with the spacers 170. This partial etching is typically stopped at the time. It has an isotropic character, and can be done wet or dry, from the second openings 200. From this partial etching, central parts of the third layers 30 are preserved under the hard masks 130, 140.

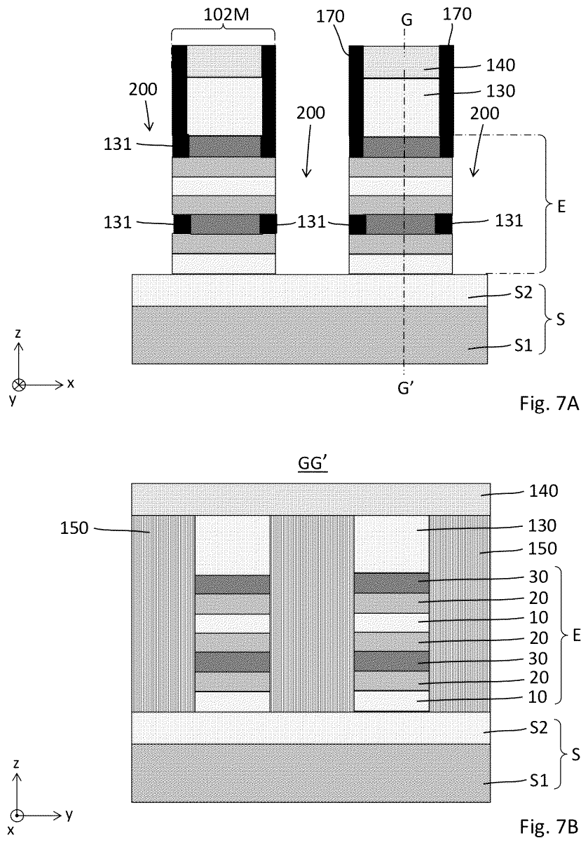

As illustrated in FIGS. 7A, 7B, the third spaces 31 are then filled with a dielectric material, for example, with silicon nitride or with a low permittivity dielectric, to form third internal spacers 131. These “internal” spacers 131 are integrated in the stack E, preferably in vertical alignment with the spacers 170. They are in contact with the central parts of the third layers 30. The formation of the third internal spacers 131 is done typically from the second openings 200.

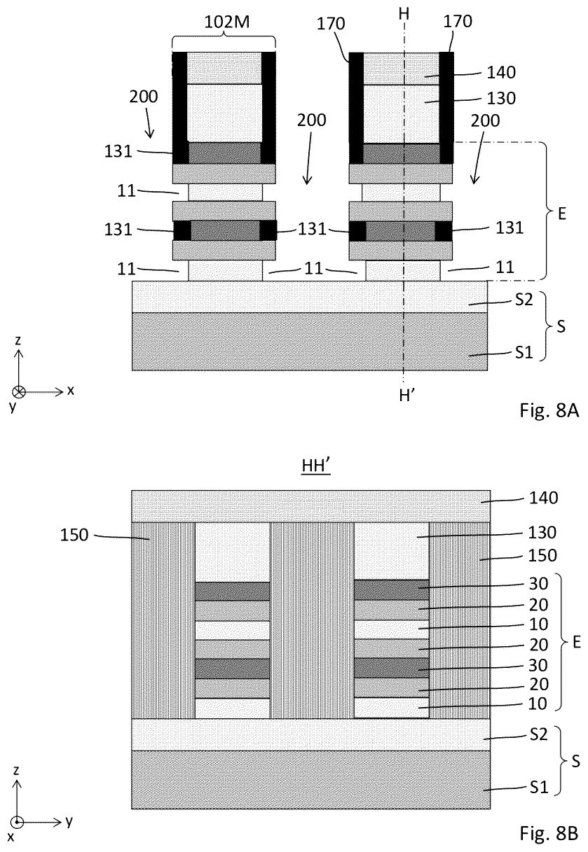

As illustrated in FIGS. 8A, 8B, the first layers 10 are partially etched selectively at the second layers 20, at the substrate S, at the spacers 170 and at the third spacers 131. The etching of the first material of the first layers 10 typically has a selectivity S_{10:20} with respect to the second material of the second layers 20, of at least 5:1, preferably at least 10:1. This partial etching aims to form first spaces 11 in vertical alignment with spacers 170 and with the third internal spacers 131. This partial etching is typically stopped at the time. It has an isotropic character and can be done wet or dry, from the second openings 200. From this partial etching, central parts of the first layers 10 are preserved under the hard masks 130, 140.

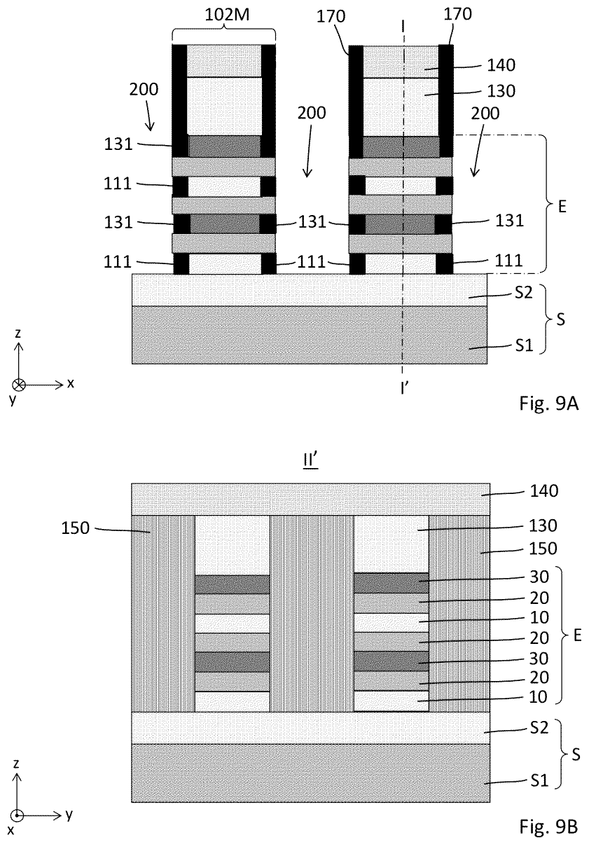

As illustrated in FIGS. 9A, 9B, the first spaces 11 are then filled with a dielectric material, for example with silicon nitride or with a low permittivity dielectric, to form first internal spacers 111. These “internal” spacers 111 are integrated in the stack E, preferably in vertical alignment with the spacers 170 and with the third internal spacers 131. They are in contact with the central parts of the first layers 10. The formation of the first internal spacers 111 is done typically from the second openings 200.

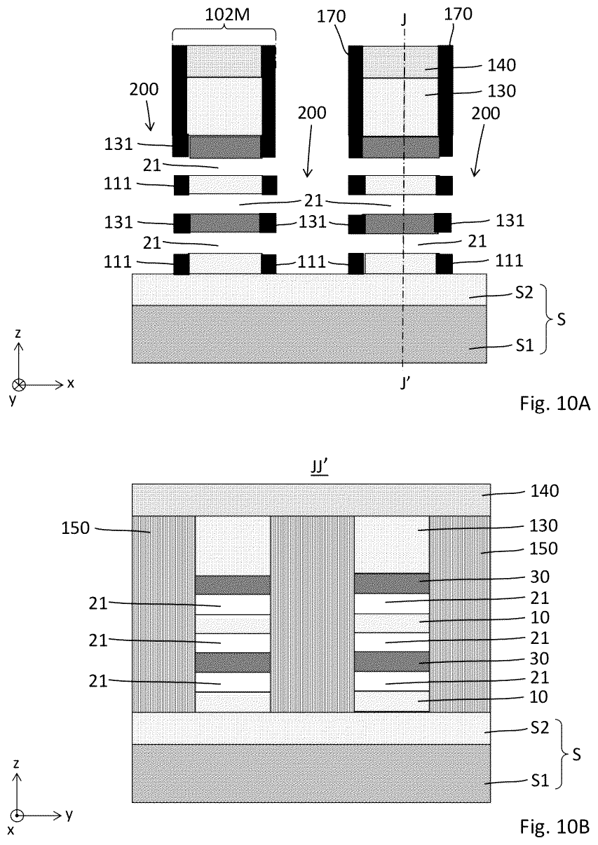

As illustrated in FIGS. 10A, 10B, the second layers 20 are then etched selectively at the central parts of the first layers 10 and third layers 30, and at the internal spacers 111, 131. The etching of the second material of the second layers 20 typically has a selectivity S_{20:10} with respect to the first material of the first layers 10, of at least 5:1, preferably at least 10:1. The etching of the second material of the second layers 20 typically has a selectivity S_{20:30} with respect to the third material of the third layers 30, of at least 5:1, preferably at least 10:1. This total etching can be stopped at the time, possibly after an overetching time aiming to guarantee the total removal of the second material from the second layers 20. This total etching has an isotropic character, and can be done wet or dry, from the second openings 200. From this etching, the second layers 20 are totally removed to form second spaces 21. The central parts of the first layers 10 and the central parts of the third layers 30 are held by the sacrificial gates 150, as illustrated in FIG. 10B.

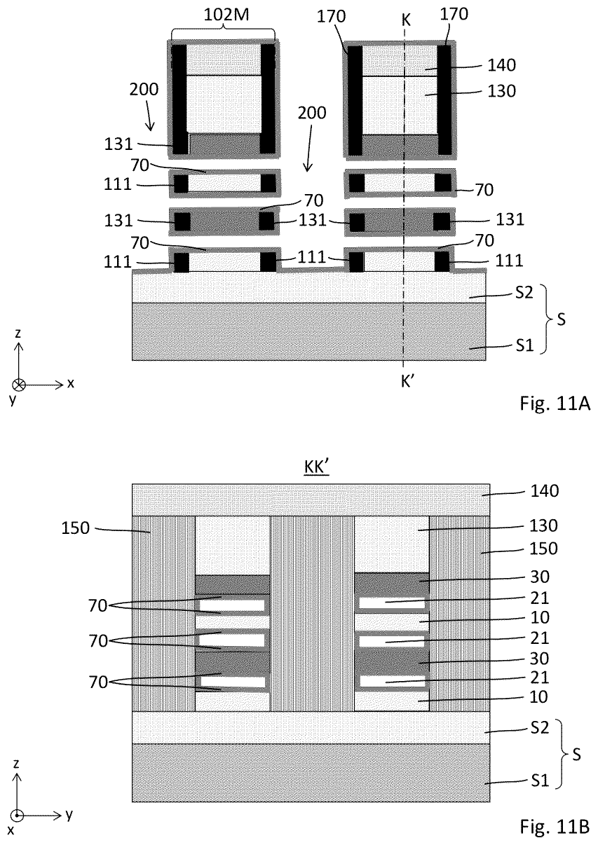

As illustrated in FIGS. 11A, 11B, a dielectric layer 70 is then deposited in the second spaces 21. This dielectric layer 70 is typically with the basis of a high permittivity material, for example, HfO2-based. The dielectric layer 70 is intended to form the gate dielectric layer between the GAA transistor channels and their gates-all-around. It can be formed by chemical vapour deposition CVD, by metal organic chemical vapour deposition MOCVD, or by atomic layer deposition ALD. It thus covers at least the central parts of the first layers 10 and the central parts of the third layers 30, and preferably, the internal spacers 111, 131, and the spacers 170. The dielectric layer 70 typically has a thickness of between 1 nm and 5 nm. According to an alternative example, this layer 70 can be with the basis of a ferroelectric material, such as Si-doped HfZrO2, HZO, HfO2, for example. Such a ferroelectric layer 70 can be advantageously used to produce FeFET (ferroelectric field-effect transistor)-type memory transistors. This dielectric layer 70 typically forms a box pattern in each pattern 102M.

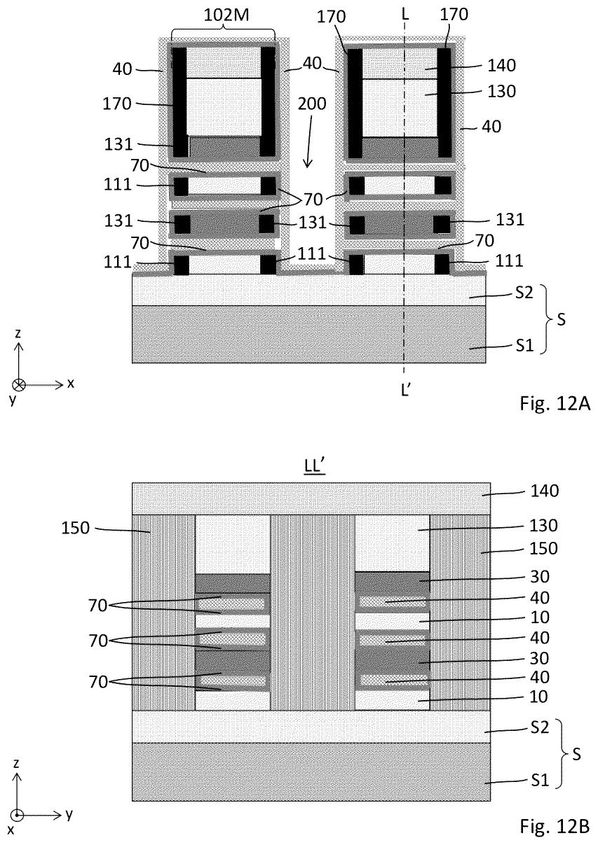

As illustrated in FIGS. 12A, 12B, a layer 40 with the basis of a semiconductive material is then deposited on the gate dielectric layer 70 in the second spaces 21. The deposition of the semiconductive material is, in this case, configured, such that the layer 40 totally fills the second spaces 21. The portions of the layer 40 located in the second spaces 21 thus have a fully controlled thickness, close to the thickness of the second initial layers. This layer 40 is intended to form the GAA transistor channels 41 in vertical alignment with the central parts of the first layers 10 and with the central parts of the third layers 30. This layer 40 is also intended to form the sources 42 and the drains 43 of the GAA transistors in vertical alignment with the spacers 170 and with the internal spacers 111, 131.

The layer 40 is also typically deposited outside of the second spaces 21, on the flanks of the spacers 170 and of the internal spacers 111, 131. This makes it possible to improve the reconnection with the sources 42 and the drains 43 of the GAA transistors. The layer 40 thus has horizontal portions in the second spaces 21, in particular, between the remaining parts of the first layers and of the third layers, and vertical portions on the flanks of the spacers 170 and of the internal spacers 111, 131. According to an option, the thickness of the vertical portions of the layer 40 is greater than the thickness of the horizontal portions of the layer 40. This makes it possible to reduce the contact resistance for the sources 42 and the drains 43 of the GAA transistors. The sources 42 and the drains 43 of the GAA transistors can comprise the horizontal portions in vertical alignment with the spacers 170 and with the internal spacers 111, 131, and at least partially, the vertical portions on the flanks of the spacers 170 and of the internal spacers 111, 131.

The semiconductive material of the layer 40 is advantageously a two-dimensional material taken from among MX2 transition metal dichalcogenides, with M, molybdenum (Mo) or tungsten (W), and X, sulphur(S), selenium (Se) or tellurium (Te). Such a 2D material can be advantageously deposited in the form of a thin layer comprising 1 to 10 atomic layers, preferably 1 to 5 atomic layers. The deposition of this 2D material can be done by CVD, MOCVD or ALD. According to another option, the semiconductive material of the layer 40 is a semiconductive oxide, such as ITO (indium tin oxide), IGZO (indium gallium zinc oxide), IWO (tungsten-doped indium oxide), In2O3 indium oxide. According to another option, the semiconductive material of the layer 40 is a graphene, a hexagonal boron nitride “h-BN”, a phosphorene (also called “Black Phosphorous” BP), in the form of a monolayer or of a thin layer comprising 1 to 10 atomic layers, preferably, 1 to 5 atomic layers.

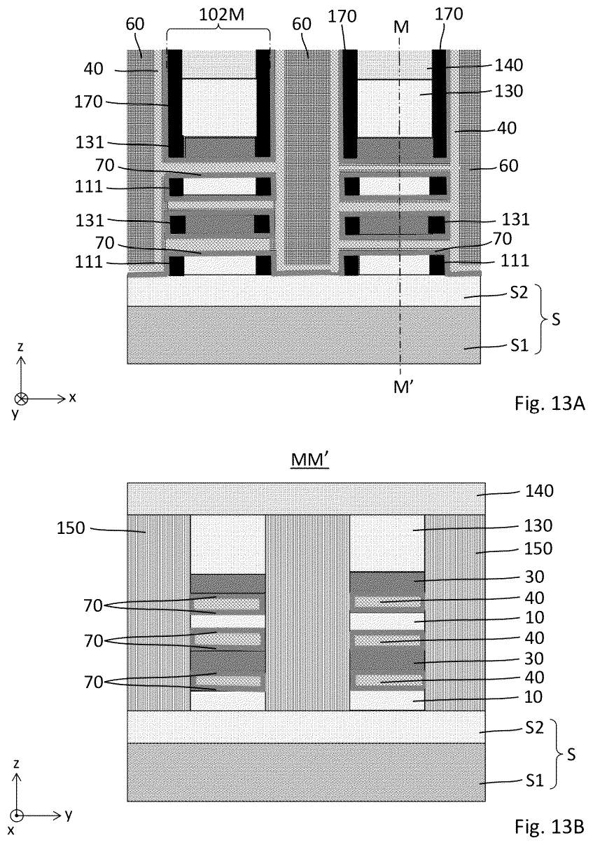

As illustrated in FIGS. 13A, 13B, the second openings can then be filled with one or more metal layers 60, for example, Ti-, TiN-, W-based, or with other metals making it possible to ensure a low contact resistance, such as Bi, Ni, Au, Sb, etc., in order to form source and drain contacts. A chemical-mechanical polishing CMP is typically done, in order to remove the excess metal deposited on the patterns 102M. The hard masks 140 are thus exposed.

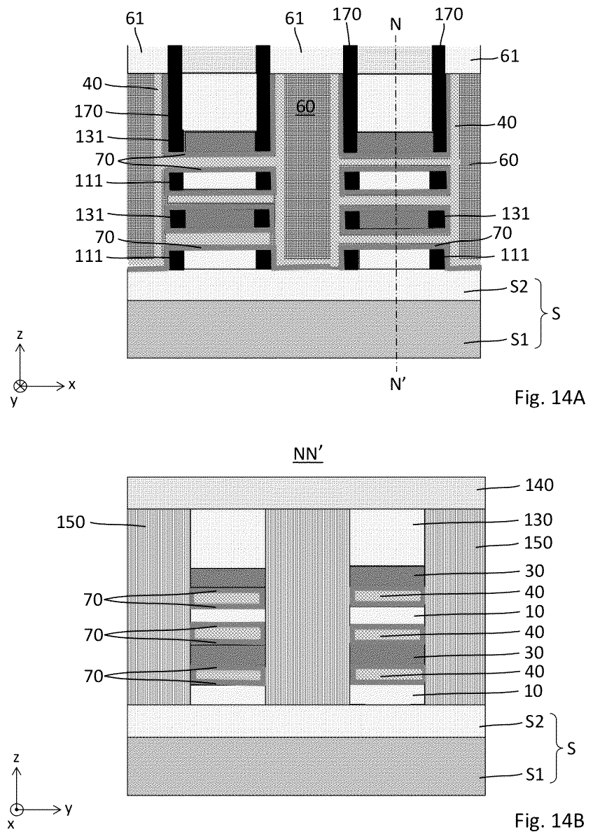

As illustrated in FIGS. 14A, 14B, protective stoppers 61, for example, SiO2-based, are preferably formed at the upper ends of the contacts 60. This makes it possible to protect the underlying metal layers, during following steps of replacing different sacrificial gate portions.

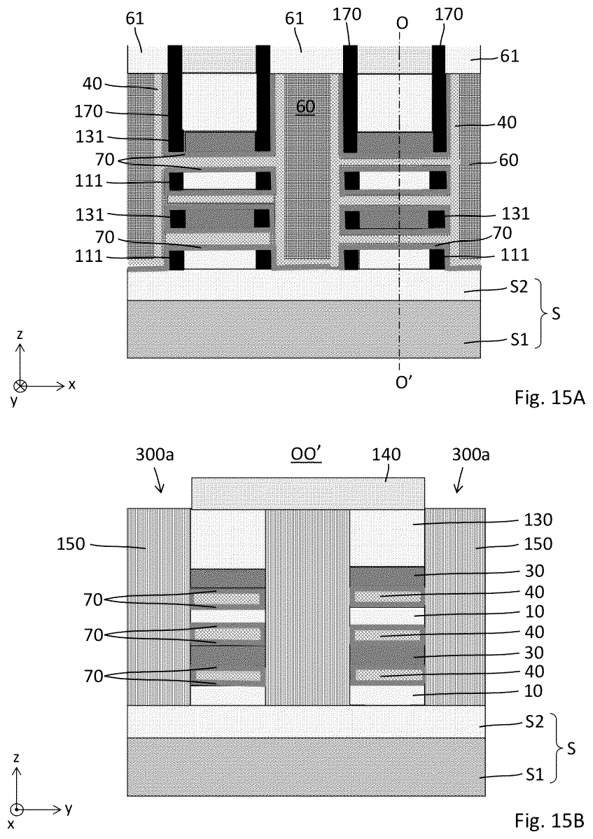

As illustrated in FIGS. 15A, 15B, the hard mask 140 is partially open to access certain portions of the sacrificial gate 150 via the openings 300a. The different portions of the sacrificial gate 150 are separated by the “fin” patterns. In particular, the openings 300a are configured to access one portion out of two of the sacrificial gate 150, alternately.

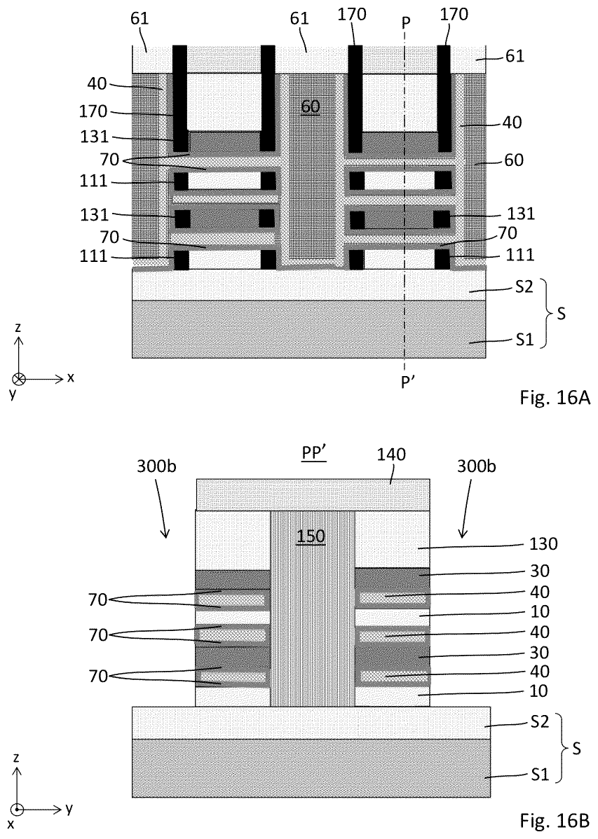

As illustrated in FIGS. 16A, 16B, the exposed portions of the sacrificial gate 150 are then removed to form the third openings 300b. This removal can be done by wet etching, stopping on the SiO2-based thin stop layer of the sacrificial gate 150. This wet etching typically has a high selectivity with respect to the stop layer. This wet etching can be with the basis of a TMAH (tetramethylammonium) or TEAH (tetraethylammonium) ammoniac salt solution. The SiO2-based stop layer is then typically etched wet to expose a first flank of the “fin” patterns. The third openings 300b open onto the central parts of the third layers 30 (FIG. 16B).

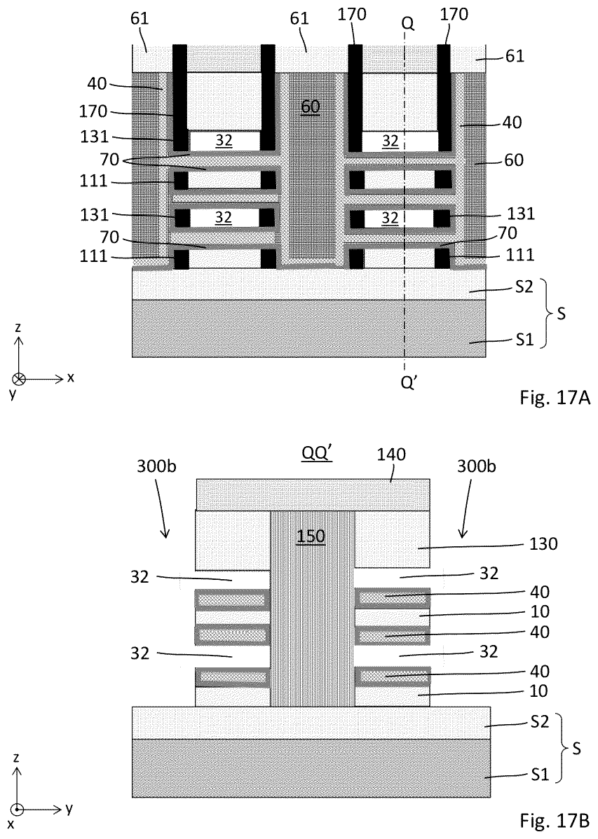

As illustrated in FIGS. 17A, 17B, the central parts of the third layers 30 are then totally removed by selective etching with respect to the dielectric layer 70 and the central parts of the first layers 10, from the third openings 300b. This etching aims to form third cavities 32 instead of the central parts of the third layers 30. This etching has an isotropic character and can be done wet or dry, from the third openings 300b.

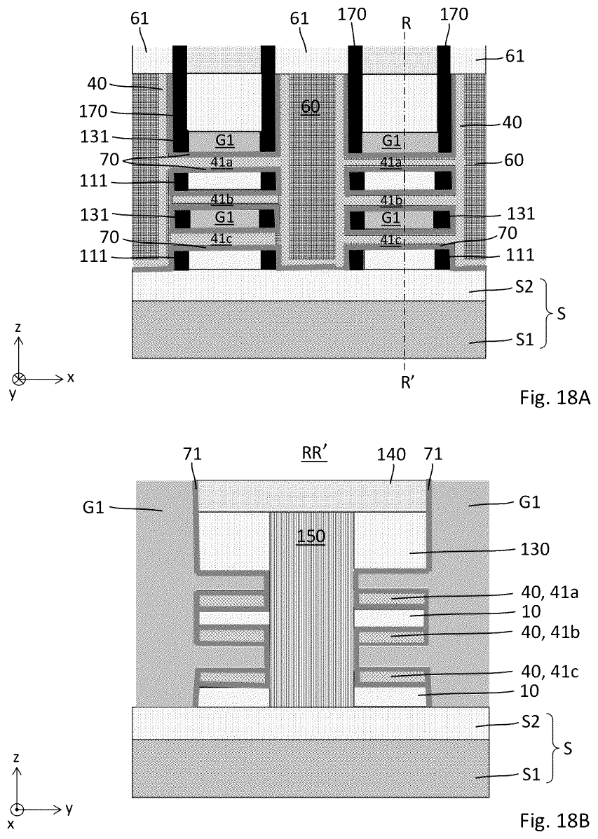

As illustrated in FIGS. 18A, 18B, the third openings 300b and the third cavities 32 are then filled with one or more metal layers, for example, TiN-, W-based, in order to form a first gate G1 of the GAA transistors. Before deposition of the metal layers, a dielectric layer 71 with the basis of a high permittivity material, for example, HfO2-based, is deposited beforehand, so as to cover the third openings 300b and the third cavities 32. This makes it possible to increase the thickness of the gate dielectric layer between the channels 41a, 41b, 41c of the GAA transistors and the first gate G1. This also makes it possible to isolate the first gate G1 with respect to the central parts of the first layers 10, intended to form a second gate part. A chemical-mechanical polishing CMP is typically done in order to remove the excess metal deposited on the patterns 102M.

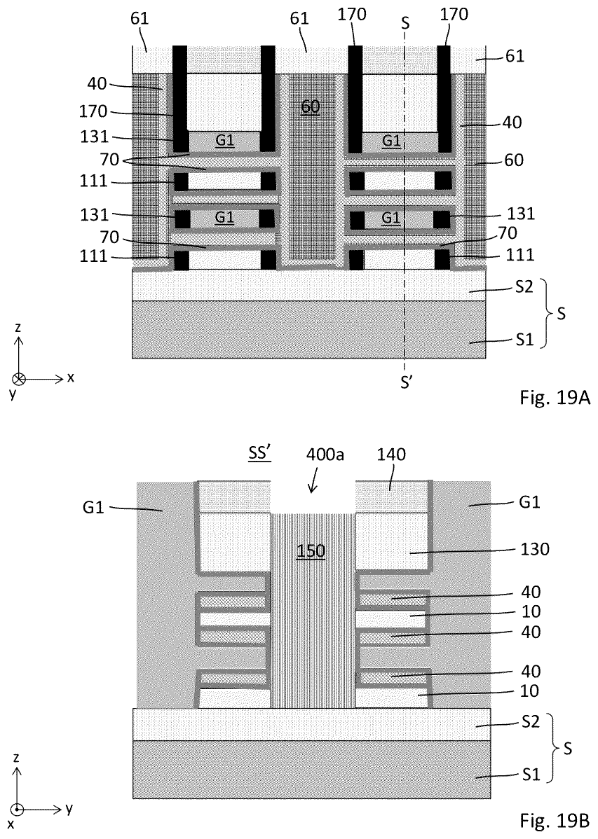

As illustrated in FIGS. 19A, 19B, the hard mask 140 is again partially open to access the remaining portions of the sacrificial gate 150, via the openings 400a.

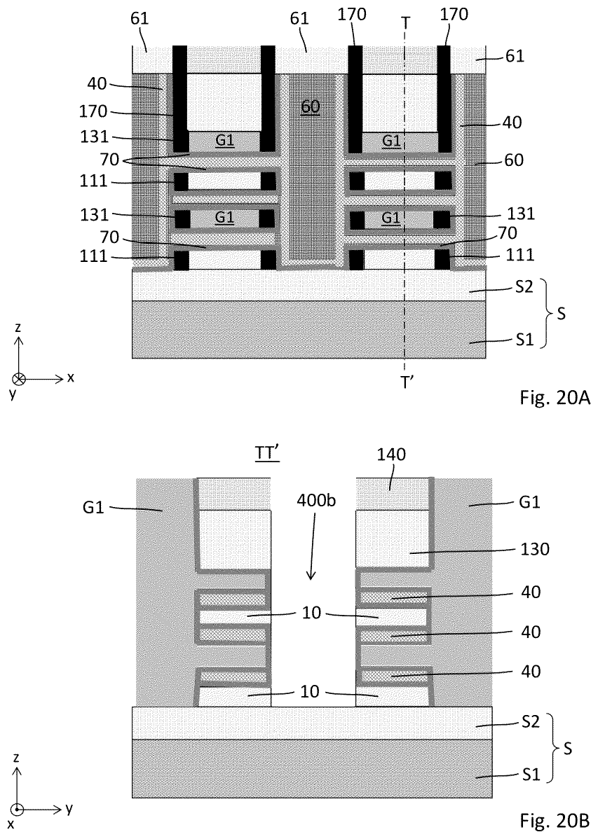

As illustrated in FIGS. 20A, 20B, the remaining portions of the sacrificial gate 150 are then removed to form the fourth openings 400b. This removal can be done as above, by TMAH-or TEAH-based wet etching, stopping on the SiO2-based thin stop layer of the sacrificial gate 150. The SiO2-based stop layer is then typically etched wet to expose a second flank of the “fin” patterns. The fourth openings 400b open onto the central parts of the first layers 10 (FIG. 20B).

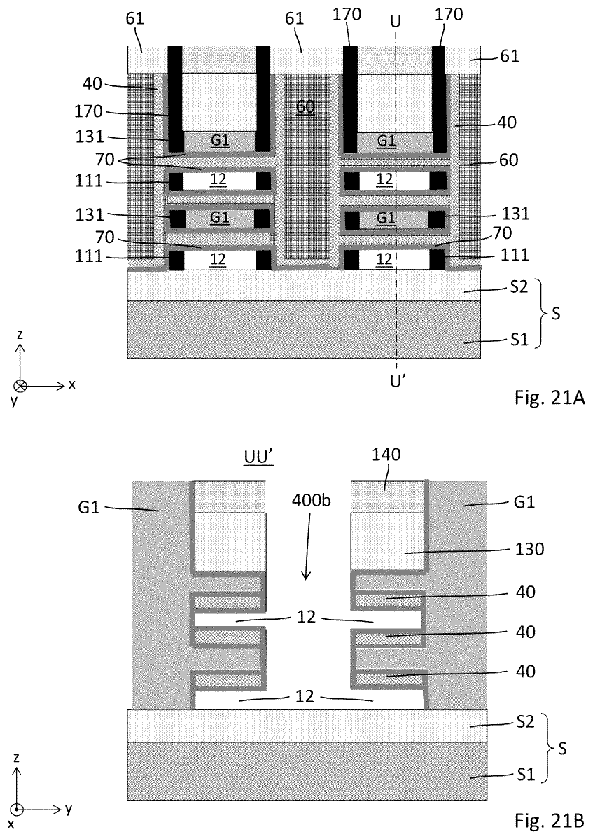

As illustrated in FIGS. 21A, 21B, the central parts of the first layers 10 are then totally removed by selective etching with respect to the dielectric layers 70, 71, from the fourth openings 400b. This etching aims to form first cavities 12 instead of the central parts of the first layers 10. This etching has an isotropic character and can be done wet or dry, from the fourth openings 400b.

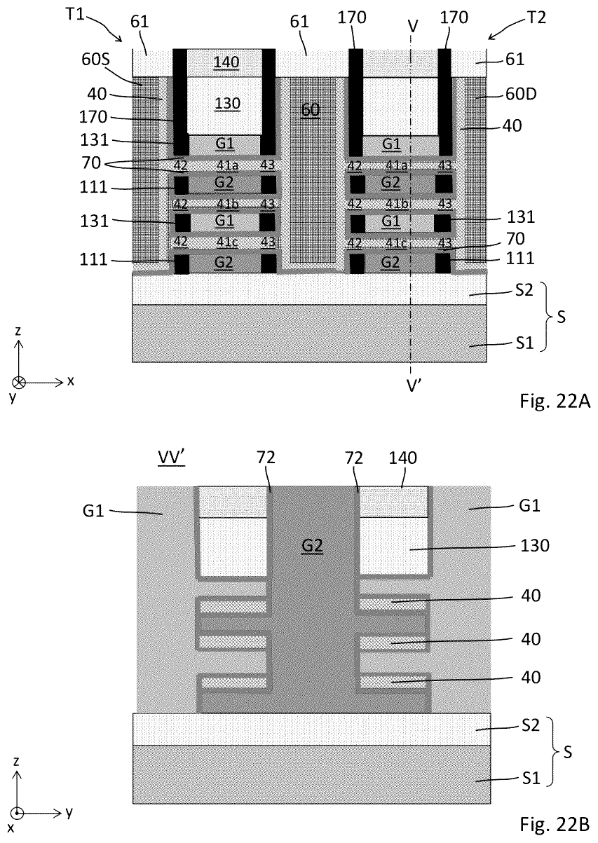

As illustrated in FIGS. 22A, 22B, the fourth openings 400b and the first cavities 12 are then filled with one or more metal layers, for example, TiN-, W-based, in order to form a second gate G2 of the GAA transistors. Before deposition of the metal layers, a dielectric layer 72 with the basis of a high permittivity material, for example, HfO2-based, is deposited beforehand so as to cover the fourth openings 400b and the first cavities 12. This makes it possible to increase the thickness of the gate dielectric layer between the channels 41a, 41b, 41c of the GAA transistors and the second gate G2. This also makes it possible to isolate the second gate G2 with respect to the first gate G1. A chemical-mechanical polishing CMP is typically done, in order to remove the excess metal deposited on the patterns 102M.

A microelectronic device comprising two transistors T1, T2, each comprising three channels 41a, 41b, 41c stacked along z, and two interdigitated gates-all-around G1, G2, is thus advantageously obtained. The channels 41a, 41b, 41c, the sources 42 and the drains 43 are preferably with the basis of a two-dimensional material. Source and drain contacts 60S, 60, 60D electrically connect these GAA transistors T1, T2.

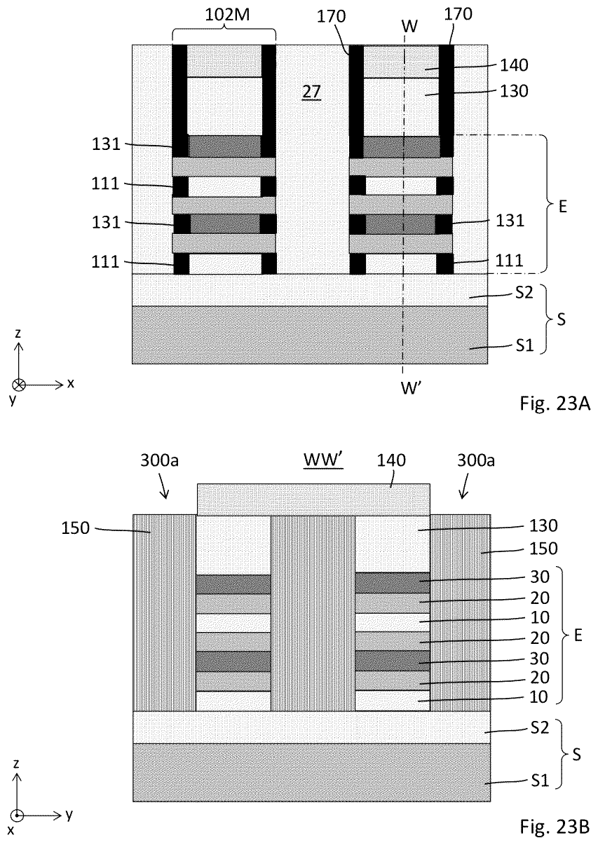

FIGS. 23A, 23B to 34A, 34B schematically illustrate steps of manufacturing a device comprising GAA transistors according to a second embodiment. Figures nA (n=23 . . . 34) correspond to first transverse cross-sections, each illustrating a different step of the manufacturing method. Figures nB (n=23 . . . 34) correspond to second transverse cross-sections, each illustrating the same step as corresponding figure nA.

Only the different features of this second embodiment with respect to the first embodiment are described below. The other features are considered identical to those of the first embodiment, in reference to the above. This second embodiment can, in particular, be qualified as “channel last”. The transistor channels are, in this case, formed after replacement of the sacrificial gate portions with the first and second gates.

As illustrated in FIGS. 23A, 23B, after formation of the internal spacers 111, 131, the second openings are filled with a dielectric material 27, for example, SiO2-based. The hard mask 140 is partially open to access certain portions of the sacrificial gate 150 via the openings 300a, as above.

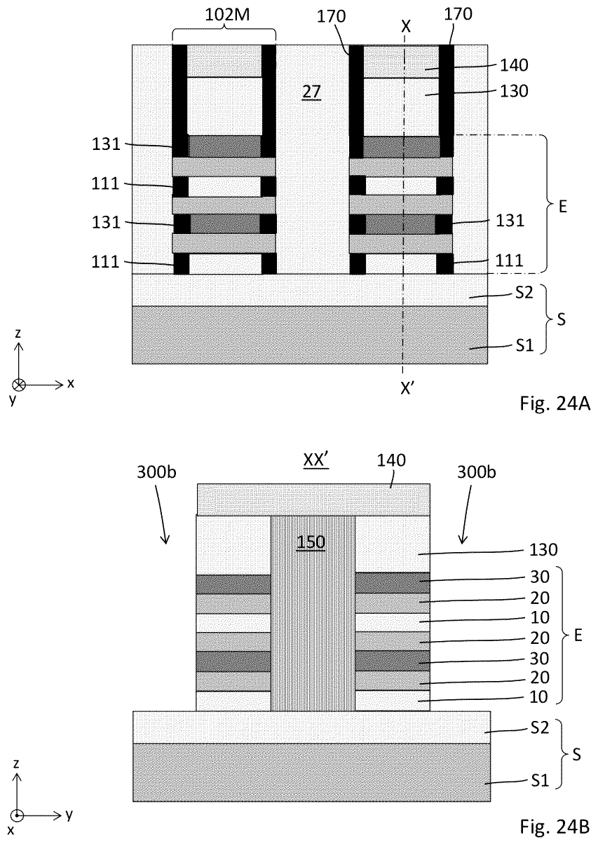

As illustrated in FIGS. 24A, 24B, the exposed portions of the sacrificial gate 150 are removed to form the third openings 300b, as above. The third openings 300b open onto the central parts of the third layers 30.

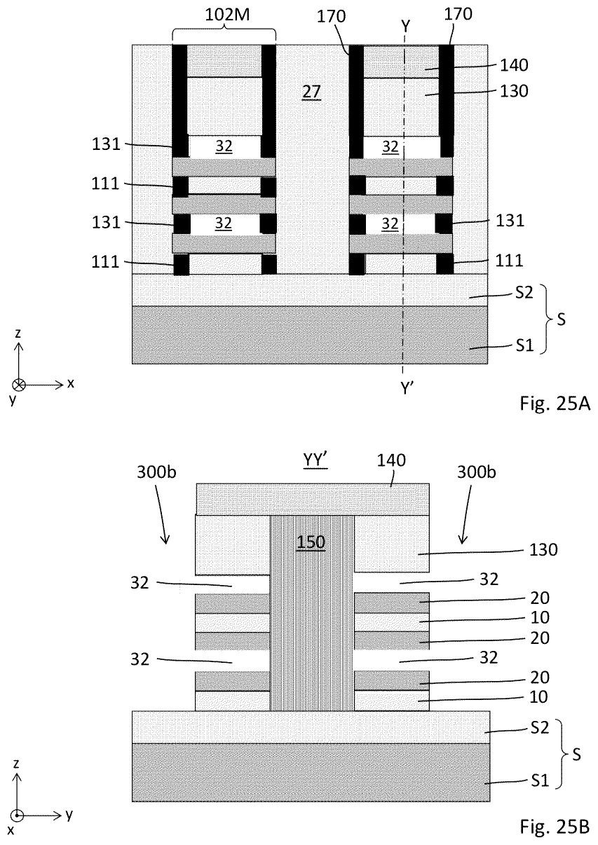

As illustrated in FIGS. 25A, 25B, the central parts of the third layers 30 are then totally removed by selective etching with respect to the second layers 20 and to the central parts of the first layers 10, from the third openings 300b. This etching aims to form third cavities 32 instead of the central parts of the third layers 30. This etching has an isotropic character and can be done wet or dry, from the third openings 300b.

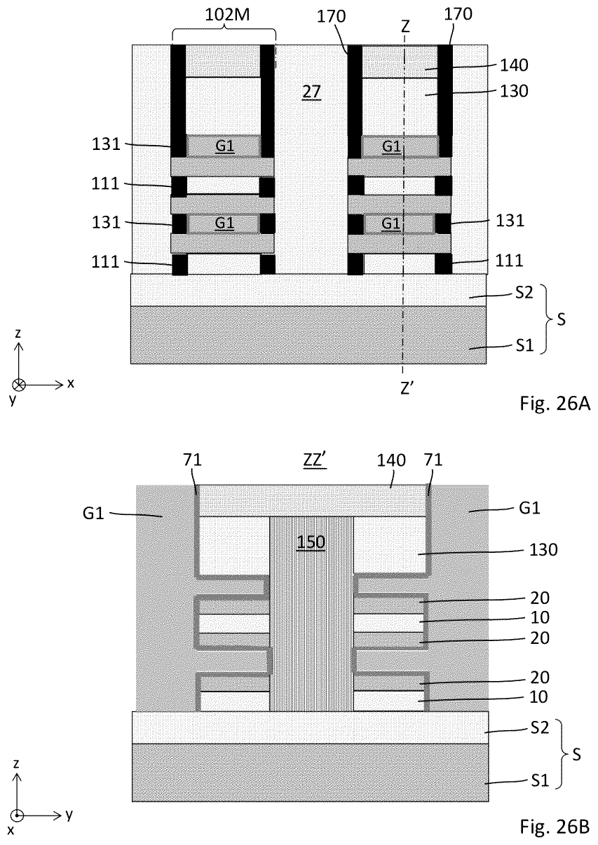

As illustrated in FIGS. 26A, 26B, the third openings 300b and the third cavities 32 are then filled with one or more metal layers, for example, TiN-, W-based, in order to form the first gate G1 of the GAA transistors. Before deposition of the metal layers, a dielectric layer 71 with the basis of a high permittivity material, for example, HfO2-based, is deposited beforehand, so as to cover the third openings 300b and the third cavities 32. This makes it possible to form the gate dielectric layer between the second layers 20, which subsequently form the GAA transistor channels, and the first gate G1. This also makes it possible to isolate the first gate G1 with respect to the first layers 10, which subsequently form the fingers of the second gate G2, as above.

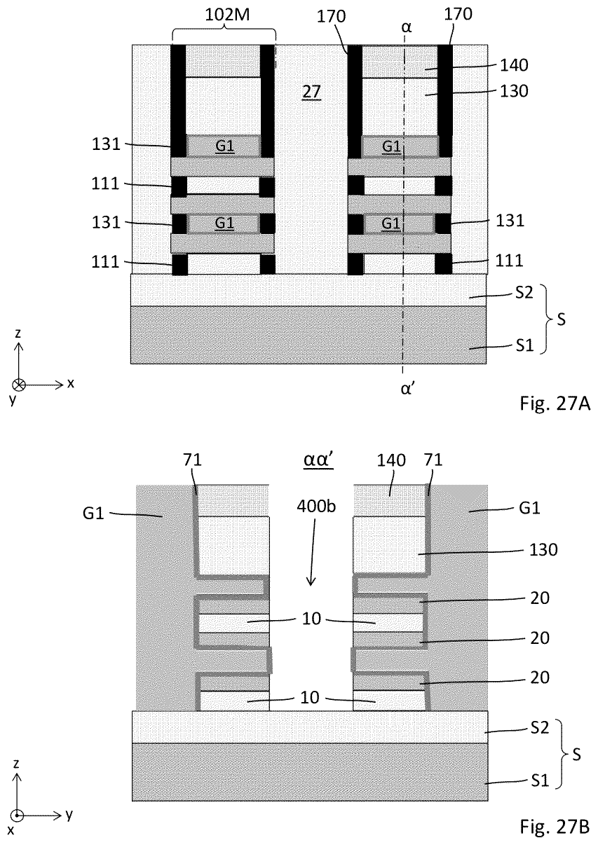

As illustrated in FIGS. 27A, 27B, the hard mask 140 is again partially open to access the remaining portions of the sacrificial gate 150, and the remaining portions of the sacrificial gate 150 are removed to form the fourth openings 400b, as above. The fourth openings 400b open onto the central parts of the first layers 10.

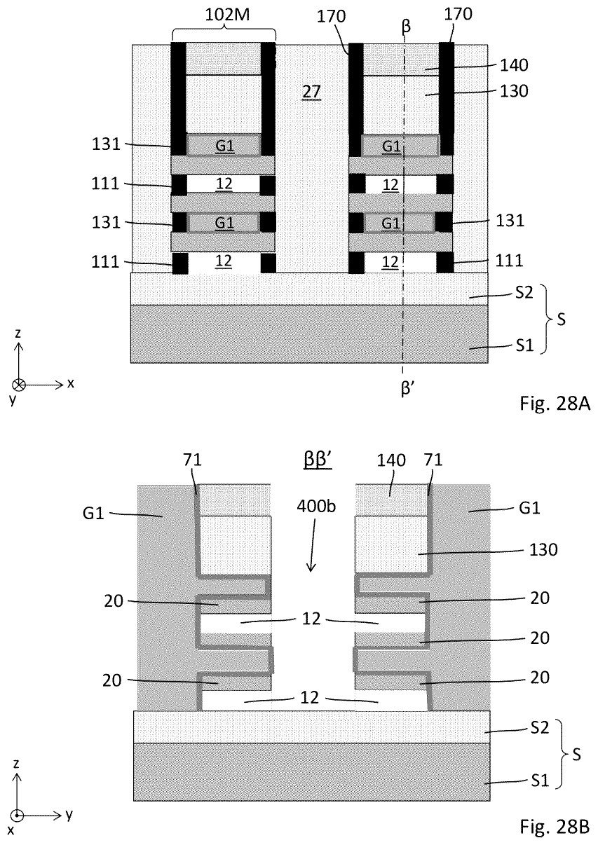

As illustrated in FIGS. 28A, 28B, the central parts of the first layers 10 are then totally removed by selective etching with respect to the dielectric layer 71 and to the second layers 20, from the fourth openings 400b. This etching aims to form the first cavities 12 instead of the central parts of the first layers 10.

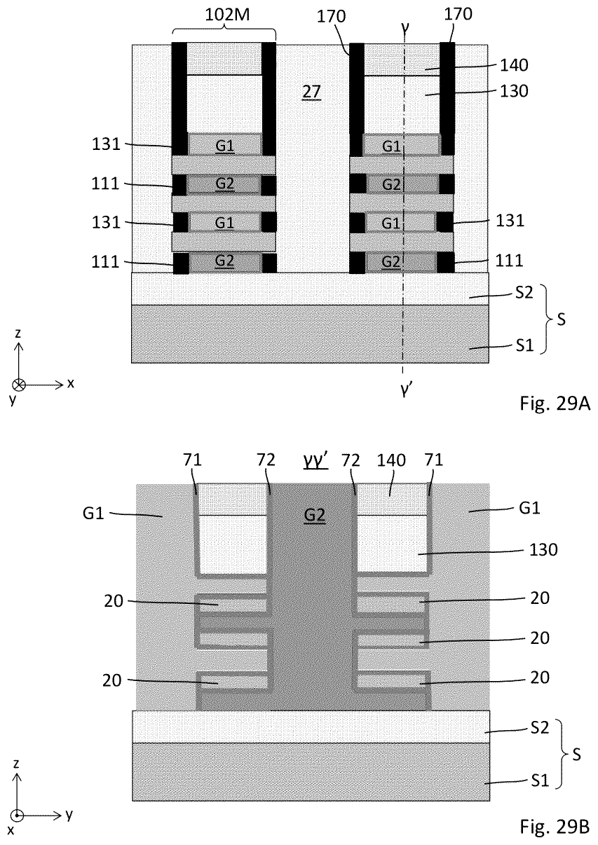

As illustrated in FIGS. 29A, 29B, the fourth openings 400b and the first cavities 12 are then filled with one or more metal layers, for example, TiN-, W-based, in order to form a second gate G2 of the GAA transistors. Before deposition of the metal layers, a dielectric layer 72 with the basis of a high permittivity material, for example, HfO2-based, is deposited beforehand, so as to cover the fourth openings 400b and the first cavities 12. This makes it possible to form the gate dielectric layer between the second layers 20, which subsequently form the GAA transistor channels, and the second gate G2. This also makes it possible to isolate the second gate G2 with respect to the first gate G1, as above.

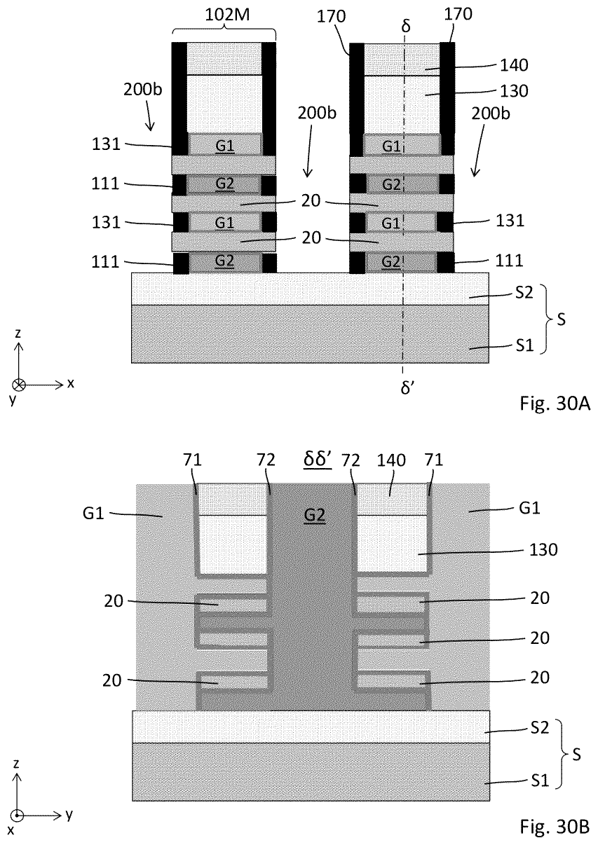

As illustrated in FIGS. 30A, 30B, the dielectric material 27 is removed, so as to reform the second openings 200b. The second openings 200b open onto the second layers 20.

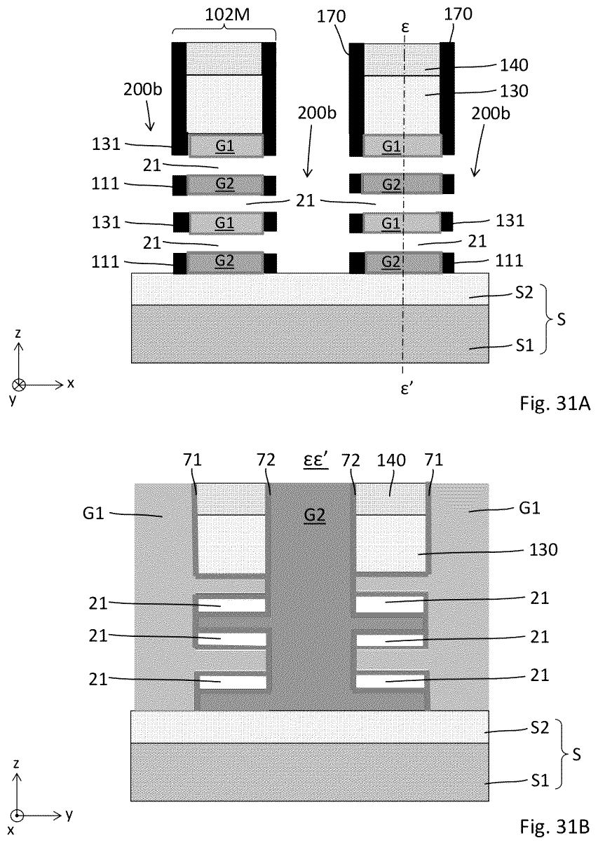

As illustrated in FIGS. 31A, 31B, the second layers 20 are then etched selectively with respect to the dielectric layers 71, 72, from the second openings 200b. This total etching can be stopped at the time, possibly after an overetching time aiming to guarantee the total removal of the second material from the second layers 20. This total etching has an isotropic character and can be done wet or dry, from the second openings 200b. From this etching, the second layers 20 are totally removed to form second spaces 21, as above.

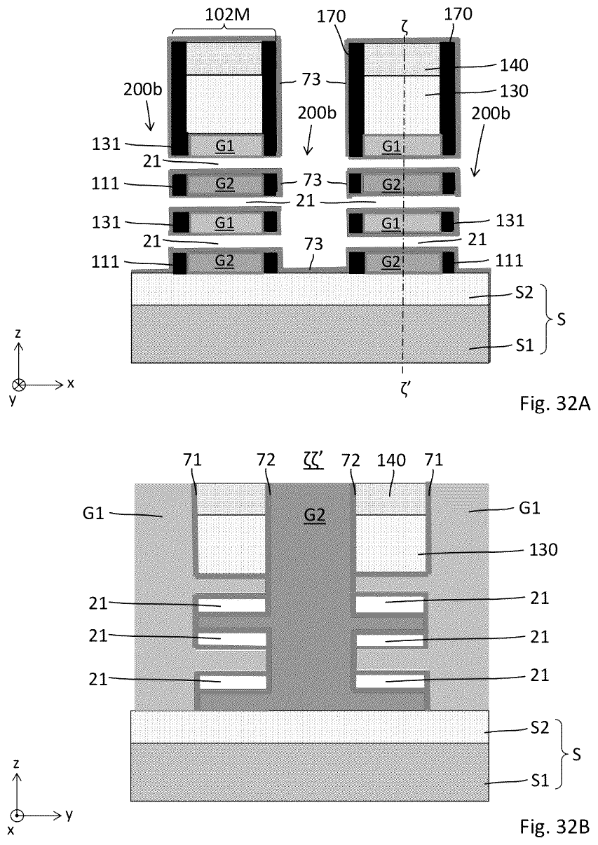

As illustrated in FIGS. 32A, 32B, according to an optional option, a dielectric layer 73 is then deposited in the second spaces 21. This dielectric layer 73 is typically with the basis of a high permittivity material, for example, HfO2-based. The dielectric layer 73 can be formed by chemical vapour deposition CVD or MOCVD, or by atomic layer deposition ALD. The dielectric layer 73 typically has a thickness of between 1 nm and 5 nm. The dielectric layer 73 typically makes it possible to increase the thickness of the gate dielectric layers formed by the dielectric layers 71, 72.

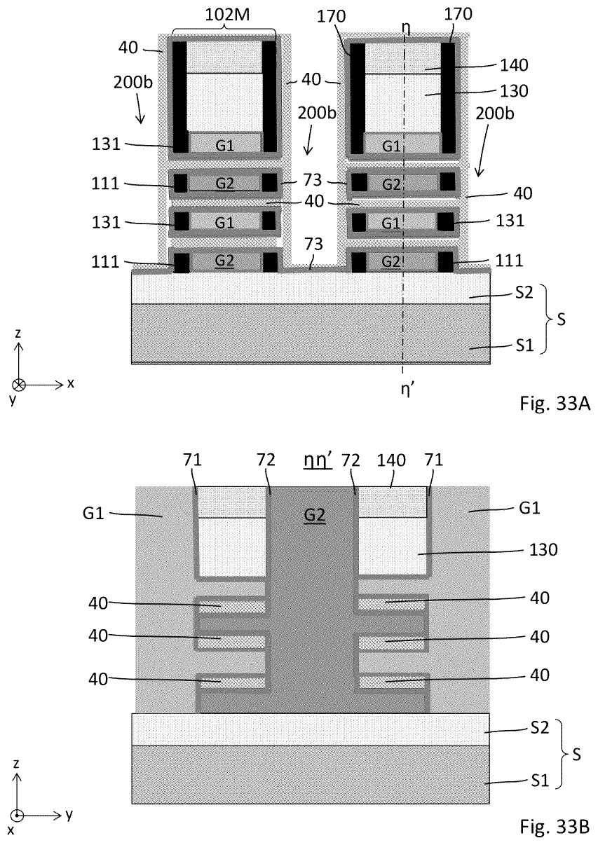

As illustrated in FIGS. 33A, 33B, the layer 40 with the basis of a semiconductive material is then deposited on the dielectric layer 73 in the second spaces 21. The deposition of the semiconductive material is, in this case, configured, such that the layer 40 totally fills the second spaces 21, as above. This layer 40 is intended to form the channels 41 of the GAA transistors in vertical alignment with the central parts of the first layers 10 and with the fingers of the gates G1, G2. This layer 40 is also intended to form the sources 42 and the drains 43 of the GAA transistors in vertical alignment with the spacers 170 and with the internal spacers 111, 131, as above.

The semiconductive material of the layer 40 is advantageously a 2D material or a semiconductive oxide, as above.

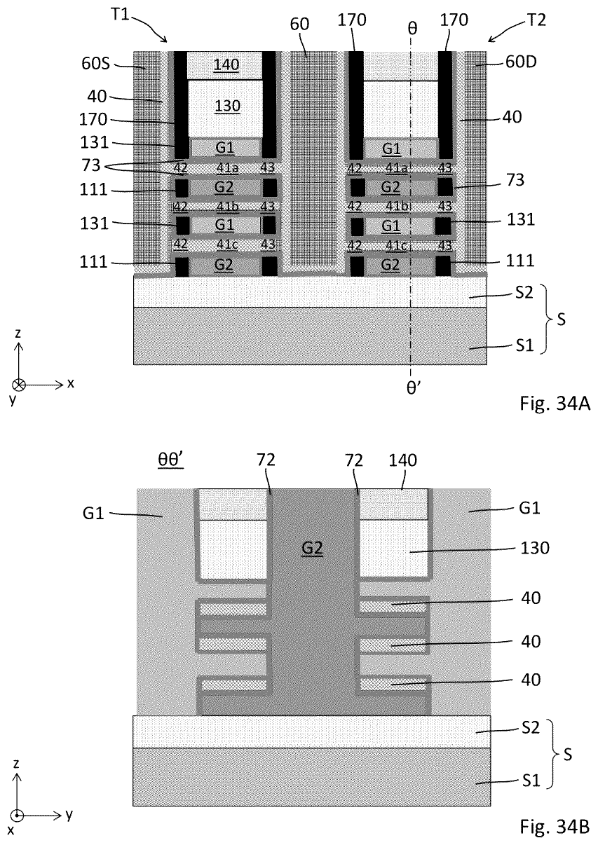

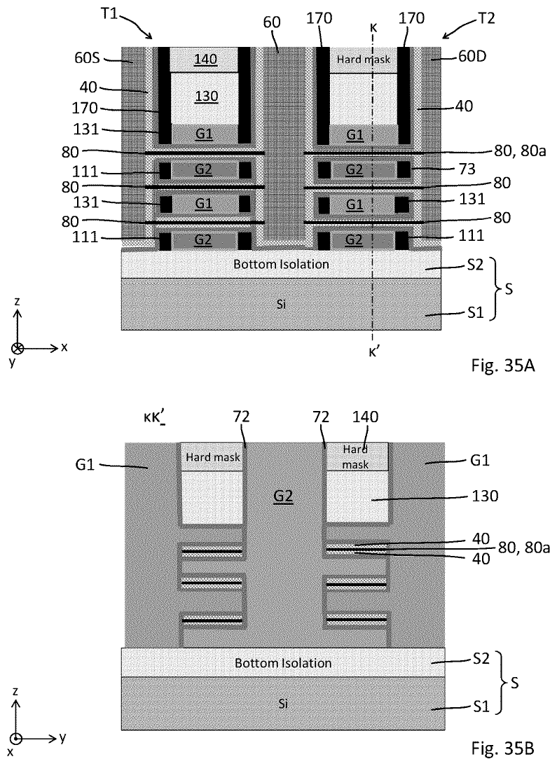

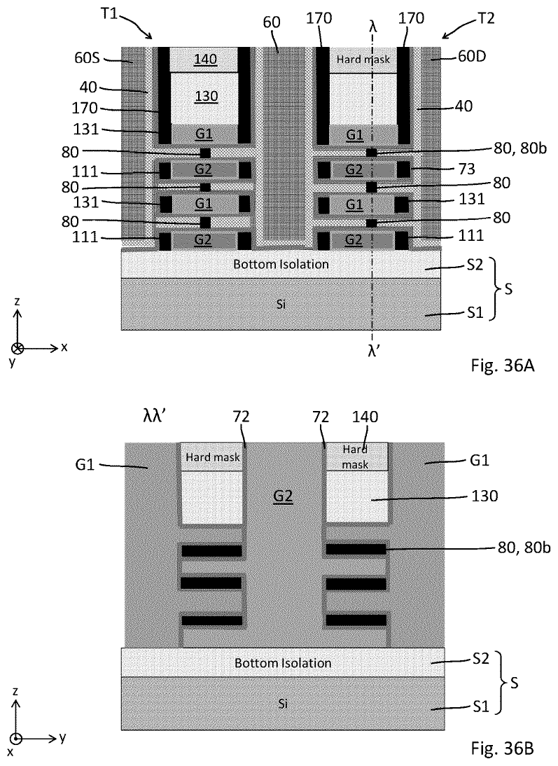

As illustrated in FIGS. 34A, 34B, the second openings can then be filled with one or more metal layers 60, in order to form the source and drain contacts as above. A chemical-mechanical polishing CMP is typically done, in order to remove the excess metal deposited on the patterns 102M.

A microelectronic device comprising two transistors T1, T2, each comprising three channels 41a, 41b, 41c stacked along z, and two interdigitated gates-all-around G1, G2, is thus advantageously obtained, as above. This second embodiment of the “channel last” type makes it possible to limit the number of technological steps to which the transistor channels are exposed during the formation of the device. The properties of the material forming the transistor channels are thus preserved.

In view of the description above, it clearly appears that the device and the method proposed offer a particularly effective solution for forming adjustable threshold voltage GAA transistors. This solution is further f advantageously compatible with standard microelectronic methods. The invention is not however limited to the embodiments described above.

According to an option not illustrated, the layer 40 with the basis of the semiconductive material does not totally fill the second spaces 21. In this case, the portions of the layer 40 located in the second spaces 21 can be significantly thinner than the second initial layers. These horizontal portions can have a thickness corresponding to only a few atomic layers, for example, between 1 and 5 atomic layers of semiconductive material. This makes it possible to reduce the dimensions of the channels 41 of the GAA transistors. The performance of the GAA transistors can be improved. A dielectric stopper is typically formed between the horizontal portions of the layer 40, in order to fill the second spaces 21. This makes it possible, in particular, to work with one single monolayer of 2D material. An excellent electrostatic control is thus obtained. The gate length can thus be advantageously reduced. This also makes it possible to improve the mechanical resistance of the device and/or to avoid deformations of the GAA transistor channels, for example, by heating during operation. This dielectric stopper can be formed by CVD deposition and etching, conventionally.

1. Microelectronic device comprising at least one transistor (T1, T2) comprising:
at least two channels (41a, 41b, 41c) stacked along a main direction (z), each channel being with the basis of a semiconductive material,
a gate (G1, G2) surrounding at least one of the channels (41a, 41b, 41c),
a source (42) and a drain (43) either side of the channels (41a, 41b, 41c), and source and drain contacts (60S, 60, 60D) connected respectively to the source (42) and to the drain (43),
a gate dielectric layer (70, 71, 72) separating each channel (41) of the gate (G1),
the device being characterised in that the gate (G1) corresponds to a first gate (G1) partially surrounding at least one of the channels (41a, 41b, 41c), and in that the at least one transistor (T1, T2) comprises a second gate (G2) partially surrounding the same channel as that surrounded by the first gate (G1), the first and second gates (G1, G2) being electrically isolated from one another, such that they can be biased independently of one another, the first gate (G1) and the second gate (G2) being interdigitated, and each channel (41a, 41b, 41c) being inserted between a finger of the first gate (G1) and a finger of the second gate (G2).

2. Device according to the preceding claim, wherein each channel (41a, 41b, 41c) is partially surrounded by the first gate (G1) and is partially surrounded by the second gate (G2).

3. Device according to any one of the preceding claims, wherein the first gate (G1) covers two adjacent sides of one of the channels (41a, 41b, 41c), and the second gate (G2) covers two other adjacent sides of said channel (41a, 41b, 41c).

4. Device according to any one of the preceding claims, wherein each finger of the first and second gates (G1, G2) only covers one single channel (41a, 41b, 41c), projecting along the main direction (z).

5. Method for manufacturing a microelectronic device according to any one of the preceding claims, said method comprising the following steps:
Providing, on a substrate(S), a stack (E) along the main direction (z) comprising a plurality of first layers (10) made of a first material, alternated with a plurality of second layers (20) made of a second material, alternated with a plurality of third layers (30) made of a third material, the first, second and third materials being different,
Forming a first etching mask (130) on this stack (E),
Forming, in this stack (E), first openings (100) defining first patterns (101M) in vertical alignment with the first etching mask (130),
Forming a sacrificial gate (150) either side of the first patterns (101M), in the first openings (100),
Forming a second etching mask (140) on the first etching mask (130) and on the sacrificial gate (150), the second etching mask (140) being transverse to the first etching mask (130),
Forming, in the first patterns (101M), second openings (200) defining second patterns (102M) in vertical alignment with the second etching mask (140),
Partially removing, from the second openings (200), the third material of the third layers (30) selectively at the first and second material of the first and second layers (10, 20), so as to form third spaces (31) in the third layers (30),
Filling the third spaces (31) with a third dielectric material to form third internal spacers (131),.
Partially removing, from the second openings (200), the first material of the first layers (30) selectively at the second material of the second layers (20) and at the third internal spacers (131), so as to form first spaces (11) in the first layers (10), preferably in vertical alignment with the third internal spacers (131),
Filling the first spaces (11) with a first dielectric material to form first internal spacers (111),
Partially removing the sacrificial gate (150) so as to form third openings (300b) opening onto the remaining parts of the third layers (30),
Totally removing, from the third openings (300b), the third material of the remaining parts of the third layers (30), so as to form third cavities (32),
Forming a first dielectric layer (71) in the third cavities (32),
Filling the third cavities (32) with a first metal material, so as to form the first gate (G1) partially surrounding the second layers (20),
Totally removing a remaining part of the sacrificial gate (150), so as to form fourth openings (400b) opening onto the remaining parts of the first layers (10),
Totally removing, from the fourth openings (400b), the first material of the remaining parts of the first layers (10), so as to form first cavities (12),
Forming a second dielectric layer (72) in the first cavities (12),
Filling the first cavities (12) with a second metal material, so as to form the second gate (G2) partially surrounding the second layers (20),
Filling the second openings (200, 200b) with an electrically conductive material, so as to form source and drain contacts in contact with the second layers (20).

6. Method according to the preceding claim, further comprising a sequence of steps configured to replace the second layers (20), said sequence comprising the following steps:
Totally removing, from the second openings (200, 200b), the second material of the second layers (20), so as to form second spaces (21),
Preferably forming a dielectric layer (70, 73) in the second spaces (21),
Depositing a layer (40) with the basis of a semiconductive material in the second spaces (21), so as to form:
channels (41a, 41b, 41c) with the basis of the semiconductive material in vertical alignment with the first and second gates (G1, G2), under the first and second etching masks (130, 140), and
sources (42) and drains (43) with the basis of the semiconductive material in vertical alignment with the first and third internal spacers (111, 131).

7. Method according to the preceding claim, wherein the sequence of steps configured to replace the second layers (20) is carried out after formation of the first and third internal spacers (111, 131), and wherein the formation of the source and drain contacts (60, 60S, 60D) is done after said sequence of steps and before the partial removal of the sacrificial gate (150).

8. Method according to claim 6, wherein the sequence of steps configured to replace the second layers (20) is carried out after formation of the first and second gates (G1, G2) and before formation of the source and drain contacts (60, 60S, 60D).

9. Method according to any one of claims 5 to 8 further comprising a formation of spacers (170) on the flanks of the first and second etching masks (130, 140), said spacers (170) bearing on an upper face (321) of the first patterns (101M).

10. Method according to any one of claims 6 to 9, wherein the semiconductive material is a two-dimensional (2D) material chosen from among MX2 transition metal chalcogenides, with M taken from among molybdenum (Mo) or tungsten (W), and X taken from among sulphur(S), selenium (Se) or tellurium (Te).

11. Method according to any one of claims 5 to 10, wherein the first layers (10) of the stack (E) are only in contact with the second layers (20), and wherein the third layers (30) of the stack (E) are only in contact with the second layers (20).

12. Method according to any one of claims 6 to 11, wherein the deposition of the layer (40) with the basis of the semiconductive material is configured, such that the layer (40) with the basis of the semiconductive material totally fills the second spaces (21).

13. Method according to any one of claims 6 to 11, wherein the deposition of the layer (40) with the basis of the semiconductive material is configured, such that the layer (40) with the basis of the semiconductive material partially fills the second spaces (21), said method further comprising, after deposition of the layer (40) with the basis of the semiconductive material, a deposition of an additional dielectric layer, configured to fill the second spaces (21).

14. Method according to any one of claims 5 to 13, wherein the first openings (100) are formed along a longitudinal direction (x) and the second openings (200) are formed along a transverse direction (y) perpendicular to the longitudinal direction (x), said first and second openings (100, 200) extending to the substrate(S).

15. Method according to any one of claims 6 to 14, wherein the deposition of the layer (40) with the basis of the semiconductive material does not totally fill the second spaces (21), such that two layer horizontal portions (40) with the basis of the semiconductive material are formed in each second space (21), and wherein a dielectric stopper (80) is formed between said two horizontal portions in each second space (21), in order to fill each second space (21).
